(19) United States
(12) Patent Application Publication
(10) Pub. No.: US 2026/0146327 A1
(43) Pub. Date: May 28, 2026

(54) MULTICHANNEL HEATED GAS DELIVERY SYSTEM

(71) Applicant: Lam Research Corporation, Fremont, CA (US)

(72) Inventors: Mark CAMPELLO, Newark, CA (US); Sushanth KONDI, Bangalore (IN); Prashant POTDAR, Dharwad (IN); Thadeous BAMFORD, Portland, OR (US); Murali Krishna JONNAGADLA RAJAGOPAL, Bengaluru (IN); Janardhan Achari Murkai SITHARAMACHARI, Bangalore (IN); Naveen PATIL, Hubli (IN)

(73) Assignee: Lam Research Corporation, Fremont, CA (US)

(21) Appl. No.: 19/099,351

(22) PCT Filed: Aug. 14, 2023
(86) PCT No.: PCT/US2023/030150

§ 371 Date: Jan. 28, 2025

Related U.S. Application Data
(60) Provisional application No. 63/371,737, filed on Aug. 17, 2022.

(51) Int. Cl. C23C 16/455

(52) U.S. Cl. CPC C23C 16/45561; C23C 16/45565; C23C 16/4557

(57) ABSTRACT

A gas conditioning assembly comprising a first block structure and at least a second block structure is disclosed. A first gas flow passage and a second gas flow passage extend within the first block structure. The first gas flow passage is adjacent to the second gas flow passage. The second block structure comprises a reservoir housing block and a reservoir yoke. The reservoir yoke comprises at least one gas reservoir within the reservoir housing block. The second block structure further comprises a nonplanar sidewall adjacent to the first block structure. The nonplanar sidewall comprises a plurality of recessed contours and a plurality of grooves extending along the nonplanar sidewall. Individual recessed contours are in thermal contact with adjacent surface mount components. Individual grooves are in thermal contact with gas line tubing sections extending from the first block structure.

### CLAIM FOR PRIORITY

This application claims priority to U.S. Provisional Ser. No. 63/371,737, filed on Aug. 17, 2022, titled “MULTICHANNEL HEATED GAS DELIVERY SYSTEM”, and which is incorporated by reference in entirety.

### BACKGROUND

Process tools are used to perform treatments such as deposition and etching of film on semiconductor wafer substrates. These process tools may comprise a vacuum chamber in which chemical vapor deposition (CVD) and atomic layer deposition (ALD) processes may be performed. Precision deposition processes such as ALD use precise delivery of precursor gases and vapors (collectively, process gases) into the vacuum chamber through a gas distribution showerhead within the vacuum chamber. Process gases may be pre-conditioned by flowing through a gas conditioning stage before passing to the showerhead. Such a gas conditioning stage may comprise arrays of interchangeable filters, heaters, mixing chambers, and flow control valves mounted on one or more modular blocks. For handling of multiple process gas streams, conventional gas conditioning stages may employ separate modular blocks for each process gas stream that is delivered to the showerhead.

Along the flow paths within the separate modular block substrates, the process gas streams may pass through a linear array of filters, mixing chambers, and flow control valves mounted on two or more substrates. Individual process gas streams may flow through a dedicated modular block substrate configured to handle a particular gas. Generally, care must be taken to avoid cold spots along the gas flow path within the block and between the block and the showerhead. In some configurations, process tool space constraints may limit conventional gas conditioning stages to only one or two gas streams. Many deposition processes require at least three process gas steams. Thus, a gas conditioning stage may be desired to provide handling of three or more process gas streams and perform all functions of the more space-consuming conventional gas conditioning stages.

### BRIEF SUMMARY

A process gas conditioning assembly is provided which comprises a surface mount substrate and process gas reservoir subassemblies in at least one embodiment. In at least one embodiment, process gas reservoir subassemblies may be adjacent to opposing lateral sidewalls, respectively, of the surface mount substrate.

In at least one embodiment, surface mount substrate can serve as a platform for attachment of a plurality of surface mount components. In at least one embodiment, one or more gas flow passages can extend within the body of surface mount substrate. In at least one embodiment, the gas flow passage may be a subsurface gas flow passage that extends within surface mount substrate. In at least one embodiment, the gas flow passage may terminate at inlet port and outlet port. Arrows within the passage indicate an exemplary gas flow path that may be established.

In at least one embodiment, the gas flow passage may comprise a plurality of segments where the plurality of segments comprise two termini that intersect at a surface. The plurality of segments may be fluidically coupled together by flow paths within surface mount components. Surface mount components may be fluidically coupled to plurality of segments and may be fluidically coupled to gas flow passage. Surface mount components may be flow control valves, gauges, pressure regulators, mass flow controllers, or mixers, for example.

In at least one embodiment, the process gas reservoir subassembly is adjacent to the surface mount substrate and comprises a reservoir housing block and a reservoir yoke, where the reservoir yoke comprises at least one gas reservoir within the reservoir housing block. In at least one embodiment, the reservoir housing block can include a nonplanar sidewall adjacent to the surface mount substrate, where the nonplanar sidewall includes a plurality of recessed contours and a plurality of grooves extending along the nonplanar sidewall. In at least one embodiment, reservoir housing blocks may comprise one or more reservoir wells in which reservoir vessels may seat. Reservoir housing blocks may comprise electric heater cartridge wells. In at least one embodiment, electric heater cartridges may seat within heater cartridge wells, providing heat to raise reservoir housing blocks to elevated temperatures. heater cartridge wells can have a cylindrical or, any suitable circumferential shape.

In at least one embodiment, the one or more recessed contours are in thermal contact with one or more surface mount components mounted on the surface mount substrate. In at least one embodiment, the and one or more grooves are in thermal contact with one or more gas line tubing sections extending from the surface mount substrate.

In at least one embodiment, gas flow passage may comprise inlet branches and/or outlet branches. Inlet branches may enable introduction of process gases such as precursor gases or vapors into gas flow passage to mix with carrier gases introduced though inlet port, for example. In at least one embodiment, process gases exiting surface mount substrate may also be preheated by thermal contact with flow passage surfaces. In at least one embodiment, heat to the flow passage surface may be supplied by heater cartridges embedded within surface mount substrate. In at least one embodiment, process gas reservoir subassemblies and may be peripheral and immediately adjacent to surface mount substrate. In at least one embodiment, components of process gas conditioning assembly, such as surface mount substrate and reservoir housing blocks and reservoir vessels may comprise chemically resistant conductive or polymer materials.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale and exact locations. For example, the dimensions of some elements may be exaggerated relative to other elements for clarity. Also, various physical features may be represented in their simplified “ideal” forms and geometries for clarity of discussion, but it is nevertheless to be understood that practical implementations may only approximate the illustrated ideals. For example, smooth surfaces and square intersections may be drawn in disregard of finite roughness, corner-rounding, and imperfect angular intersections characteristic of structures formed by nanofabrication techniques. Further, where considered appropriate, reference labels have been repeated among the figures to indicate corresponding or analogous elements.

FIG. 1A illustrates a plan view of a process gas conditioning assembly, according to at least one embodiment.

FIG. 1B illustrates a cross-sectional view of the process gas conditioning assembly of FIG. 1A, according to at least one embodiment.

FIG. 1C illustrates a profile view in a y-z plane of a sidewall of a process reservoir housing block subassembly of the process gas conditioning assembly shown in FIG. 1A, according to at least one embodiment.

FIG. 1D illustrates a plan view in an x-y plane of the process gas conditioning assembly shown in FIG. 1A, that further comprises a heated endplate, according to at least one embodiment.

FIG. 1E illustrates a profile view in an x-z plane of the heated endplate shown in FIG. 1D, according to at least one embodiment.

FIG. 2 illustrates an exploded oblique view of a process gas reservoir subassembly, according to at least one embodiment.

FIG. 3A illustrates a plan view in the x-y plane of a process gas conditioning assembly comprising a single reservoir bank, according to at least one embodiment.

FIG. 3B illustrates a profile view in the x-z plane of the process gas conditioning assembly shown in FIG. 3A, according to at least one embodiment.

FIG. 3C illustrates a profile view in the x-z plane of a process gas conditioning assembly comprising horizontally oriented process gas reservoirs, according to at least one embodiment.

FIG. 4A illustrates a profile view in the x-z plane of a process gas conditioning assembly, according to some embodiments of the disclosure.

FIG. 4B illustrates a profile view in the x-z plane of a process gas conditioning assembly, according to at least one embodiment.

FIG. 4C illustrates a plan view in the x-y plane of a process gas conditioning assembly, according to at least one embodiment.

FIG. 5A illustrates a plan view in the x-y plane of a process gas conditioning assembly comprising three process gas flow paths, according to at least one embodiment.

FIG. 5B illustrates a profile view in the x-z plane of the process gas conditioning assembly shown in FIG. 5A, according to some embodiments of the disclosure.

FIG. 6A illustrates an exploded plan view in the x-y plane of a preheater assembly, according to at least one embodiment.

FIG. 6B illustrates a cross sectional view in the y-z plane of the preheater assembly of FIG. 6A, according to at least one embodiment.

FIG. 6C illustrates a plan view in the x-y plane of a process gas conditioning assembly comprising preheater assemblies, according to at least one embodiment.

FIG. 6D illustrates a profile view in the x-z plane of the process gas conditioning assembly comprising preheater assemblies as shown in FIG. 6C, according to at least one embodiment.

FIG. 7 illustrates a cross-sectional view in the x-z plane of a semiconductor processing tool comprising a process gas conditioning assembly, according to at least one embodiment.

FIG. 8 illustrates a method flow chart for operating a process gas conditioning assembly, according to at least one embodiment.

### DETAILED DESCRIPTION

Disclosed herein is a compact modular gas conditioning assembly comprising a multi-flow passage surface mount substrate block and at least one process gas reservoir housing block subassembly. In at least one implementation, two process gas reservoir housing block subassemblies may be adjacent to the multi-flow passage surface mount substrate block. The multi-flow passage surface mount substrate block (henceforth, “substrate”) may comprise two or more process gas flow passages within a unitary monolithic block, in accordance with some embodiments. In at least one implementation, the two or more process gas flow paths may be machined sub-surface passages within the unitary substrate block. In at least one implementation, the three or more process gas flow paths may be adjacent and substantially parallel to one another within the substrate. In at least one implementation, the substrate may comprise heater cartridges housed within wells formed in the substrate. In at least one implementation, the heater cartridges may be located at predetermined positions within the substrate to heat the substrate to substantially uniform elevated temperatures.

Process gases may include inert carrier gases such as nitrogen or argon, reactive gases such as hydrogen, ammonia, hydrazine, oxygen, ozone, or water vapor. Process gases may also include precursor gases and vapors of precursor substances that are normally solid or liquid at room temperature. In general, process gases may be heated to elevated temperatures. The elevated temperature may enable surface reactions within a deposition chamber. In some processes, gases may be heated to, for example, 500° C. or more. Precursor vapors may be heated to elevated temperatures to avoid condensation or crystallization along flow paths. Some of the process gases may also be corrosive. To withstand adverse conditions, components of the process gas conditioning assembly may comprise a high-temperature machinable material having substantial resistance to chemical attack, in accordance with some embodiments. Thus, the substrate may comprise materials such as, but not limited to, stainless steel or high-temperature nickel alloys such as Hastelloy. Other suitable materials, such as metal alloys comprising titanium, tungsten, or tantalum may also be included. In at least one implementation, the substrate may comprise high-temperature chemically resistant polymers such as polyether ether ketone (PEEK) or fluoropolymers (e.g., Teflon).

In at least one implementation, the substrate may include a plurality of surface mount gas conditioning and flow control components (henceforth, “surface mount components”). The surface mount components may comprise surface-mountable gas filters, valves, and mixing chambers, as well as other suitable gas handling components. A plurality of apertures on the mounting surface of the substrate may enable fluidic communication between the surface mount components and the multiple gas flow paths within the substrate. In at least one implementation, a first set of apertures may be fluidically coupled to a first gas flow passage. In at least one implementation, a second set of apertures may be fluidically coupled to a second flow passage, etc. In at least one implementation, individual apertures may be grouped into groups of two or three apertures, where the apertures are fluidically coupled to an individual surface mount component. Internal flow passages within the individual surface mount components may be included as part of the process gas flow path.

In at least one implementation, the process gas conditioning assembly comprises a process gas reservoir subassembly. In at least one implementation, the process gas reservoir subassembly may comprise a reservoir housing block and a removable reservoir yoke subassembly. In at least one implementation, the reservoir yoke subassembly comprises one or more charge volume cannisters (e.g., reservoir vessels) that seat within wells in the reservoir housing block. In at least one implementation, the reservoir housing block may comprise a plurality of heater cartridges to maintain gases or vapors contained within the reservoir vessels at predetermined temperatures. In at least one implementation, individual heating cartridges may be positioned within heating cartridge wells distributed within the reservoir housing block. In at least one implementation, the number and location of the heater cartridges may be predetermined to provide sufficient heat to maintain the reservoir housing blocks at predetermined temperatures.

In at least one implementation, predetermined temperatures may exceed 300° C. during operation. To withstand such temperatures, in some embodiments the block housing and reservoir vessel subassemblies may comprise high temperature, chemically resistant materials, such as stainless steel, Hastelloy, ceramics, or high-temperature polymers such as PEEK.

While the substrate may be heated by a plurality of heater cartridges, surface mount components that are attached to the substrate have high surface-to-volume ratios and may be more difficult to maintain at elevated temperatures. As a result, the surface mount components may harbor cold spots and be prone to plugging by condensation of process vapors. Thermal insulation placed around and between surface mount components may not be sufficient above certain temperatures to mitigate condensation. To guard against condensation, in at least one implementation, the process gas reservoir subassembly comprises a non-planar sidewall comprising a plurality of contours. The contours may be complementary to the shape of adjacent surface mount components mounted on the substrate to maximize the contact area of between the surface mount components and the sidewall of the reservoir housing block. The sidewall contours may be in direct contact with adjacent surface mount components or in very close proximity through a small gap. Small gaps or intimate contact between surfaces of surface mount components and the scalloped sidewall of the reservoir housing block may facilitate temperature control of the surface-mounted components.

In at least one implementation, the reservoir housing block may also comprise deep grooves extending along the scalloped sidewall for accommodating gas line tubing transporting carrier gases. In at least one implementation, the gas line tubing may be coupled to gas flow paths within the substrate. In at least one implementation, the deep grooves in the reservoir housing block sidewall may maintain the tubing at elevated temperatures to preheat carrier gases and mitigate condensation of precursor vapors.

In some instances, in the following description, well-known methods and devices are shown in block diagram form, rather than in detail, to avoid obscuring the present disclosure. Reference throughout this specification to “an embodiment” or “one embodiment” or “some embodiments” means that a particular feature, structure, function, or characteristic described in connection with the embodiment is included in at least one embodiment of the disclosure. Thus, the appearances of the phrase “in an embodiment” or “in one embodiment” or “some embodiments” in various places throughout this specification are not necessarily referring to the same embodiment of the disclosure. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

Here, “coupled” and “connected,” along with their derivatives, may be used to describe functional or structural relationships between components. These terms are not intended as synonyms for each other. Rather, in particular embodiments, “connected” may be used to indicate that two or more elements are in direct physical, optical, or electrical contact with each other. Here “coupled” may be used to indicate that two or more elements are in either direct or indirect (with other intervening elements between them) physical, electrical or in magnetic contact with each other, and/or that the two or more elements co-operate or interact with each other (e.g., as in a cause an effect relationship). Here, “coupled” may also generally refer to direct attachment of one electronic component to another. An electric or magnetic field may couple one component to another, where the field is controlled by one component to influence the other in some manner.

Here, “over,” “under,” “between,” and “on” may generally refer to a relative position of one component or material with respect to other components or materials where such physical relationships are noteworthy. Unless these terms are modified with “direct” or “directly,” one or more intervening components or materials may be present. Similar distinctions are to be made in the context of component assemblies. As used throughout this description, and in the claims, a list of items joined by the term “at least one of” or “one or more of” can mean any combination of the listed terms.

Here, “adjacent” may generally refer to a position of a thing being next to (e.g., immediately next to or close to with one or more things between them) or adjoining another thing (e.g., abutting it).

Here, “assembly” may generally refer to an apparatus comprising multiple components that individually may only be functional when assembled together.

Here, “subassembly” may generally refer to portions of an assembly. The subassembly may comprise a subset of the total number of components that make up the total assembly. In at least one implementation, subassemblies are sections of the overall assembly. In at least one implementation, an engine block subassembly of an engine assembly may comprise the engine block, crankshaft, and pistons. In at least one implementation, an engine block subassembly may not be functional by itself. In at least one implementation, an engine assembly may use the fuel delivery subassembly and other subassemblies to work in conjunction with the engine block subassembly.

Here, “block structure” may generally refer to a structure that is generally rectilinear. In at least one implementation, a block may a solid mass of material (e.g., steel) having a substantially rectilinear three-dimensional form factor. In at least one implementation, a block may be milled and bored by standard machining tools, or formed additively, for example by 3D printing.

Here, “gas conditioning” may generally refer to a process precondition a process gas for a downstream process. In at least one implementation, preconditioning may comprise stages of filtering, pressure regulating, flow rate regulating and preheating or cooling of the process gas. In at least one implementation, a downstream process may be a chemical vapor deposition.

Here, “process gas” may generally refer to an inert or reactive carrier gas, such as argon, nitrogen, oxygen, or hydrogen. In at least one implementation, a substance may be considered as a gas if the substance is in the gaseous state at room temperature. In at least one implementation, a process gas may also contain or be a vapor of a precursor substance. In at least one implementation, in a process gas, a precursor substance is generally in a vapor state at an elevated temperature, either by sublimation or boiling. In at least one implementation, a vapor may condense or crystallize at temperatures below a critical temperature.

Here, “gas conditioning assembly” may generally refer to an apparatus comprising multiple components that are configured to condition process gases (e.g., as defined herein) that travel from a source to a semiconductor process tool, such as a chemical vapor deposition tool.

Here, “precursor substance” may generally refer to a chemical substance that can undergo a surface or gas phase reaction to transform into a solid film on a surface during a deposition process. In at least one implementation, a precursor may be a chemical reactant that is involved the surface or gas phase reaction to create a surface film.

Here, “aperture” may generally refer to a hole, an orifice, or an opening on a surface. In at least one implementation, an opening may be the intersection of a subsurface passage with a surface of a block structure or other type of structure. for example.

Here, “groove” may generally refer to an elongated shallow cut or trench on a surface.

Here, “surface mount substrate”, or simply “substrate”, may generally refer to a plate or block having a subsurface flow passage for transport of gases or liquids. In at least one implementation, a substrate comprises a mounting surface, upon which surface mountable valves, filters, pressure regulators, gauges, tubing couplers, etc., may be bolted. In at least one implementation, mounting surface comprises a plurality of apertures that align to inlet and outlet ports on the bottom flanges of the surface mount components. In at least one implementation, apertures are fluidically coupled to the internal flow path. In at least one implementation, by alignment of fluid ports on the bottoms of the surface mount components to the surface apertures, the surface mount components may be in-line with the subsurface flow passage. In at least one implementation, coupling may be serial, so that the fluid may be forced to flow through the surface mount component.

Here, “surface mount component” may generally refer to modular valves, flow controllers, gauges, filters, pressure regulators, and the like, that may comprise a base flange that bolts onto a surface mount substrate. In at least one implementation, a surface mount substrate may be configured to flow a gas or liquid through a subsurface flow passage to which a series of apertures along a row or column are fluidically coupled by tapping into the flow path at intervals along the flow passage. In at least one implementation, apertures may be aligned to inlet and outlet ports on the bottoms of multiple surface mount components, where liquids or gases may serially enter the surface mount components fluidically coupled to the same subsurface flow passage. In at least one implementation, multiple surface mount components may be coupled to the same subsurface flow passage by attaching to the substrate along a row or column of apertures following the subsurface flow path.

Here, “gas flow passage” may generally refer to a conduit integral within a block structure, for example a substrate as defined above, enabling transport and distribution of gases, that extends within the interior of the surface mount substrate. In at least one implementation, subsurface flow passage may comprise individual internal U-or V-shaped segments that extend obliquely within the body of the substrate. In at least one implementation, segments may intersect the mounting surface of the substrate. A surface aperture may open into the segments at the points of intersection. In at least one implementation, unconnected internal segments of the subsurface flow passage may enable surface mount components to be part of the flow path. Serial flow of the fluid through surface mount components may be enabled such that the fluid (e.g., gas or liquid) may flow through a series of surface mount components. In at least one implementation, fluid may be filtered in one component and pressure regulated in a following component, etc.

Here, “surface mount gas handling components” may generally refer to surface mount components that are specialized for gases.

Here, “fluidically coupled” may generally refer to components that are coupled in such a way that fluids (e.g., gases or liquids) may flow from one component to the other. In at least one implementation, a conduit may be fluidically coupled to a vessel when it opens into the interior of the vessel, enabling a fluid to flow between the conduit and the vessel.

Here, “reservoir” may generally refer to a vessel for containing a gas or liquid or storage and as a container source of flow of the gas or liquid.

Here, “gas reservoir” may generally refer to a vessel for containing a gas. The vessel may be a pressure vessel, for example. In at least one implementation, the gas may be a process gas. In at least one implementation, a process gas may be employed in a chemical vapor deposition process such as a pressurized gas cylinder. In at least one implementation, a reservoir may be a charge volume cannister as defined herein.

Here, “charge volume” may generally refer to a volume of a process gas. The process gas may be a charge within a gas reservoir.

Here, “charge volume cannister” may generally refer to a cannister-shaped gas reservoir holding a gas charge. In at least one implementation, the charge may generally refer to the gas charge within the cannister and the gas may generally be under pressure. In at least one implementation, the volume may generally refer to the volume of the cannister. In at least one implementation, a cannister may be generally have a cylindrical form factor.

Here, “process gas reservoir” may generally refer to a subassembly of a process gas conditioning assembly that comprises a reservoir housing block and a reservoir yoke.

Here, “reservoir yoke” may generally refer to a structure comprising a gas distribution manifold yoke fluidically and mechanically coupled to at least one gas reservoir. In at least one implementation, a gas reservoir may be a charge volume cannister, for example. In at least one implementation, a manifold yoke may provide rigid mechanical support for the at least one reservoir (e.g., charge volume cannister). In at least one implementation, a manifold yoke may comprise a conduit enabling fluidic coupling between two or more gas reservoirs.

Here, “reservoir housing block” may generally refer to a block that comprises wells for seating one or more gas reservoirs (e.g., charge volume cannisters). In at least one implementation, reservoir housing block may be machined from block stock, or formed additively, for example, by 3D printing.

Here, “nonplanar sidewall” may generally refer to a sidewall of the gas reservoir subassembly block that comprises nonplanar features relative to a reference plane, such as recessed contours.

Here, “recessed contour” may generally refer to a contour recessed below the reference plane of a sidewall of gas reservoir subassembly (e.g., the nonplanar sidewall). In at least one implementation, a contour may comprise a circular or noncircular arc.

Here, “gas line tubing” may generally refer to metal or polymer tubing that is employed to transport gases from one point to another within a system of gas line tubing sections or segments.

Here, “gas line tubing sections” may generally refer to small lengths of gas line tubing.

Here, “riser” may generally refer to a gas line tubing section that extends substantially vertically.

Here, “preheater assembly” may generally refer to a component of the process gas conditioning assembly through which gas line tubing sections pass for preheating gases flowing through them. In at least one implementation, a preheater assembly may be in line with gas line tubing entering the substrate, or with gas line tubing sections entering the charge volumes. In at least one implementation, a preheater assembly may comprise multiple plates arranged in a stack assembly. In at least one implementation, gas line tubing sections may pass between adjacent plates in the stack assembly.

Here, “stack assembly” may generally refer to multiple plates assembled into a stack.

Here, “thermal contact” may generally refer to conductive heat transfer between two surfaces that are mechanically connected or in very close proximity. For the latter condition, a small gap (e.g., one millimeter or less) may be present between the first surface and the second surface.

Here, “heater cartridges” may generally refer to electrical heating elements in a cylindrical package. In at least one implementation, heater cartridges may generally be housed within wells of similar dimensions that may be formed within the gas reservoir subassembly block, for example, and the surface mount substrate.

Here, “heater cartridge well” may generally refer to a blind hole, or well, formed in a block structure within which a heater cartridge may be inserted and seated.

Here, “heated panel” may generally refer to a block structure that comprises heater cartridges. In at least one implementation, a heated panel may be a structure comprising a nonplanar sidewall as defined herein. In at least one implementation, a heated panel subassembly may be similar to a reservoir housing block in that the heated panel comprises a nonplanar sidewall but may not comprise reservoir wells.

Here, “semiconductor process tool” may generally refer to an apparatus comprising a vacuum chamber wherein integrated electronic circuits and micro electromechanical systems (MEMS) devices may be fabricated on semiconductor wafers. In at least one implementation, semiconductor wafers may be treated by a variety of deposition and etch processes that are typically conducted in a high vacuum. In at least one implementation, a high vacuum may be developed within the vacuum chamber.

Here, “showerhead” may generally refer to a gas dispensing manifold that is employed in the vacuum chamber of a semiconductor process tool. In at least one implementation, a showerhead may comprise a plurality of apertures through which process gases may be dispersed into the vacuum chamber. In at least one implementation, a showerhead may be fed by process gases passing through a gas conditioning assembly or directly from a process gas source. In at least one implementation, a showerhead may be employed in a semiconductor process tool vacuum chamber.

Here, “showerhead inlet adapter” may generally refer to a block through which exit conduits from a process gas conditioning assembly may traverse to mechanically couple to a showerhead. In at least one implementation, the showerhead inlet adapter may comprise a lumen (e.g., a tubular cavity) through which the exit conduits may extend. In at least one implementation, the exit conduits may terminate at annular apertures opening into chambers of the showerhead.

Here, “conduit” may generally refer to a pipe or tubing that conveys a gas or a liquid.

Here, “annular aperture” may generally refer to a ring-shaped opening or an aperture.

Here, “vacuum chamber” may generally refer to a chamber that is pumped down to a high vacuum. In at least one implementation, vacuum chambers may be employed in semiconductor process tools for fabrication of integrated circuits and MEMS devices. In at least one implementation, deposition, cleaning and etch processes are most commonly carried out in the vacuum chamber.

Unless otherwise specified in the explicit context of their use, the terms “substantially equal,” “about equal,” and “approximately equal” may generally mean that there is no more than incidental variation between two things so described. In the art, such variation is typically no more than +/−10% of the referred value.

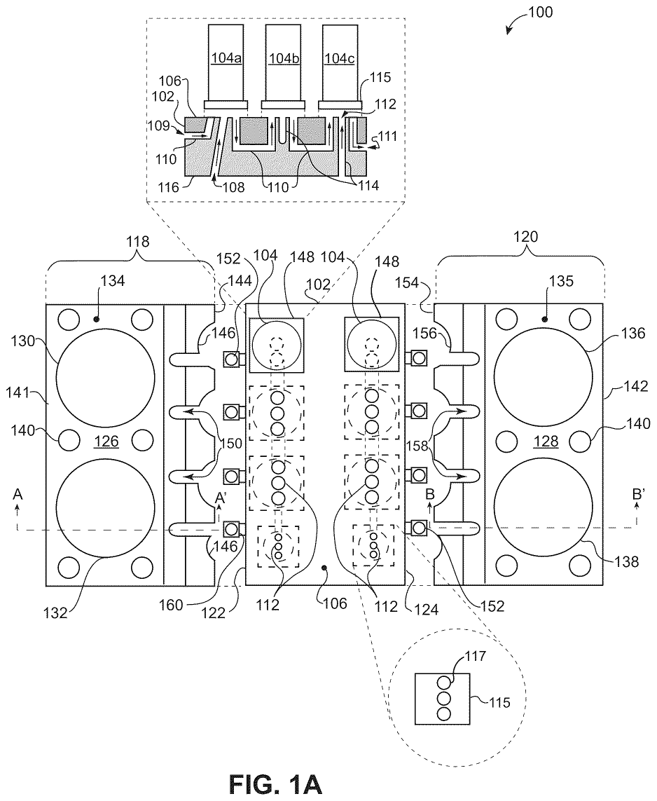

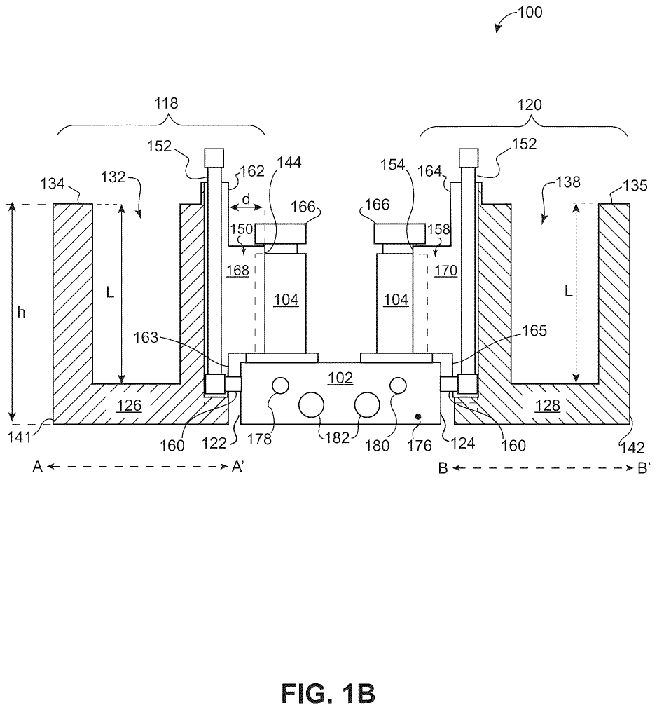

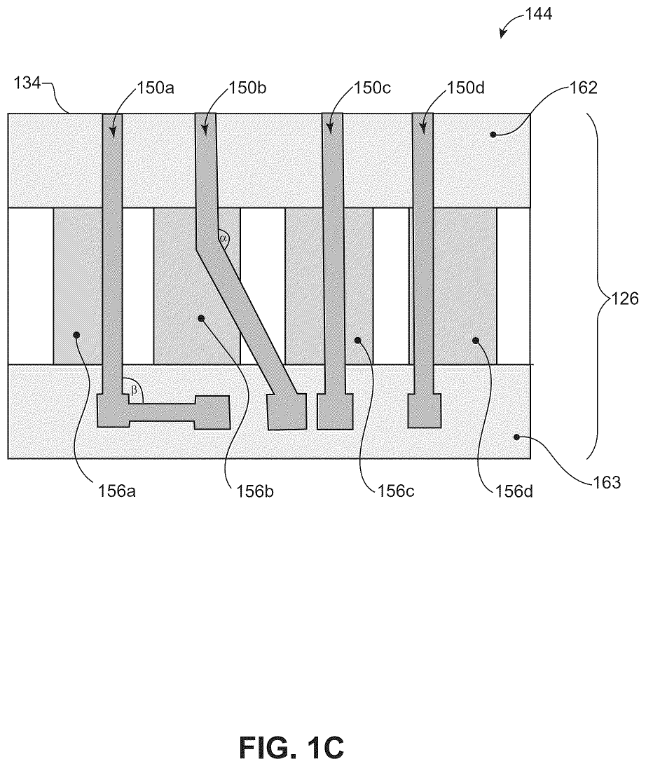

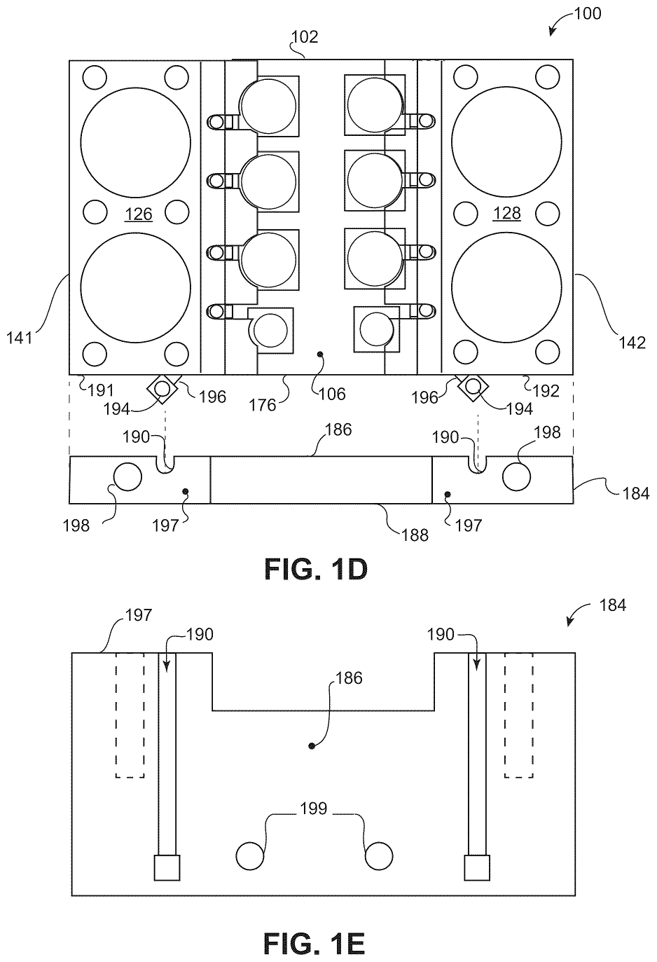

FIG. 1A illustrates a plan view in the x-y plane of process gas conditioning assembly 100, in accordance with at least one implementation. In at least one implementation, process gas conditioning assembly 100 comprises a surface mount substrate 102 and process gas reservoir subassemblies 118 and 120, respectively. In at least one implementation, process gas reservoir subassemblies 118 and 120 may be adjacent to opposing lateral sidewalls 122 and 124, respectively, of surface mount substrate 102.

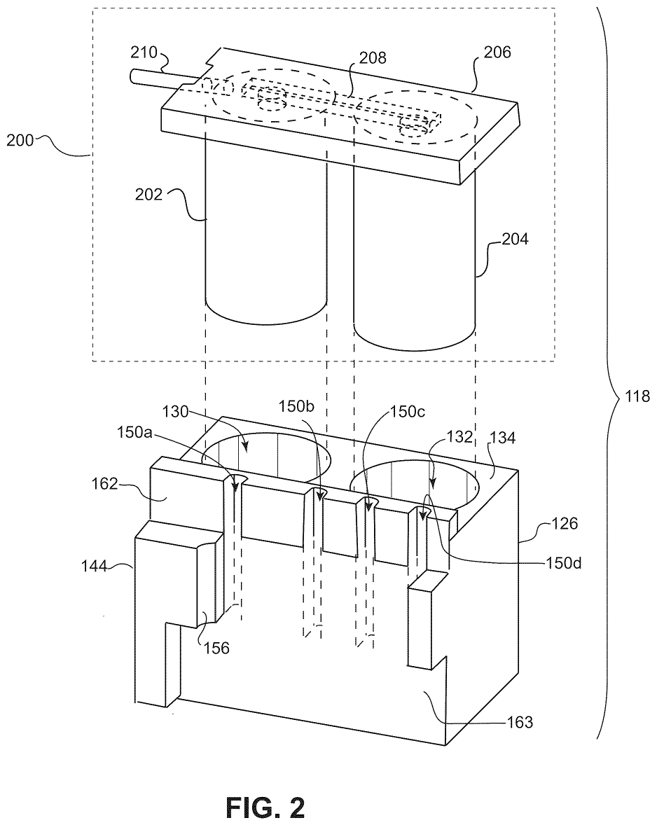

In at least one implementation, process gas reservoir subassemblies 118 and 120 may comprise reservoir housing blocks 126 and 128, respectively. In at least one implementation, process gas reservoir subassemblies 118 and 120 may further comprise a reservoir yoke, such as reservoir yoke 200 shown in FIG. 2.

In at least one implementation, surface mount substrate 102 may serve as a platform for attachment of a plurality of surface mount components 104 attached to surface 106, which may be a mounting surface of surface mount substrate 102. In at least one implementation, gas flow passage 108 may extend within the body of surface mount substrate 102, below surface 106. A cross-sectional illustration of gas flow passage 108 is shown in the upper inset in FIG. 1A. In at least one implementation, a flow passage, flow passage 108, is shown. In at least one implementation, multiple flow passages may exist. In at least one implementation, gas flow passage 108 may be a subsurface gas flow passage that extends within surface mount substrate 102 below surface 106. In at least one implementation, gas flow passage 108 may terminate at inlet port 109 and outlet port 111. Arrows within the passage indicate an exemplary gas flow path that may be established. In at least one implementation, such as is shown, gas flow passage 108 may comprise a plurality of segments 110, that may terminate on surface 106. In at least one implementation, plurality of segments 110 comprise two termini that intersect surface 106. In at least one implementation, at points of intersection with surface 106 may be apertures 112.

In at least one implementation, plurality of segments 110 may be fluidically coupled together by flow paths within surface mount components 104. In at least one implementation, surface mount components 104 may be fluidically coupled to plurality of segments 110 and may be fluidically coupled to gas flow passage 108. In at least one implementation, surface mount components 104 may be flow control valves, gauges, pressure regulators, mass flow controllers, or mixers, for example. In at least one implementation, surface mount components 104 may also comprise filters and other gas conditioning components. In at least one implementation, cavities (not shown) within surface mount components 104 (e.g., labelled 104a, 104b and 104c) may be in-line with gas flow passage 108, thus part of the gas flow path. In at least one implementation, gas flow passage 108 may comprise inlet branches and/or outlet branches 114.

For clarity, some surface mount components 104 may be indicated by dashed circles within the dashed boxes in the figure to show underlying apertures 112 on surface 106 of surface mount substrate 102. In at least one implementation, apertures 112 may be segregated into groups of two or three, corresponding to inlet and outlet ports at the bottom of surface mount components. In at least one implementation, apertures 112 may be fluidically coupled to gas flow passages (e.g., gas flow passage 108) (also indicated by the hidden lines extending between sets of apertures 112 in the plan view) within surface mount substrate 102. In at least one implementation, surface mount components 104 may be mounted by bolting to flanges 115 to surface 106. In at least one implementation, bolts may be threaded through bolt holes (not shown) in flanges 115 to engage receiving bolt holes (not shown) on surface 106. In at least one implementation, ports 117 on the bottom of flanges 115 (shown in lower inset) may be aligned to grouped apertures 112. In at least one implementation, apertures 112 are counterbored to accommodate o-rings.

In at least one implementation, inlet branches may enable introduction of process gases such as precursor gases or vapors into gas flow passage 108 to mix with carrier gases introduced though inlet port 109, for example. In at least one implementation, outlet branches may enable diversion of process gases to a branching flow path from gas flow passage 108 or venting of gases to the atmosphere. In at least one implementation, inlet branches may terminate on a surface other than surface 106, such as lower surface 116 or at a sidewall. In at least one implementation, process gases exiting surface mount substrate 102 through outlet port 111 may be preconditioned by surface mount components. In at least one implementation, process gases exiting surface mount substrate 102 may also be preheated by thermal contact with flow passage surfaces. In at least one implementation, heat to the flow passage surface may be supplied by heater cartridges embedded within surface mount substrate 102, as described below.

In at least one implementation, process gas reservoir subassemblies 118 and 120 may be peripheral and immediately adjacent to surface mount substrate 102. In at least one implementation, process gas conditioning assembly 100 comprises dual process gas reservoir subassemblies 118 and 120. In at least one implementation, process gas conditioning assembly 100 may comprise a process gas reservoir subassembly (e.g., either process gas reservoir subassembly 118 or process gas reservoir subassembly 120, respectively). In at least one implementation, process gas reservoir subassemblies 118 and 120 may be respectively adjacent to opposing lateral sidewalls 122 and 124 of surface mount substrate 102. In at least one implementation, process gas reservoir subassemblies 118 and 120 comprise reservoir housing block 126 and reservoir housing block 128, respectively.

In at least one implementation, process gas reservoir subassemblies 118 and 120 further comprise a process gas reservoir subassembly, such as reservoir yoke 200 shown in FIG. 2 and described herein. In at least one implementation, reservoir yoke 200 may comprise one or more reservoir vessels. For clarity, the reservoir subassemblies are omitted in the plan view of FIG. 1A, which shows reservoir housing blocks 126 and 128.

In at least one implementation, components of process gas conditioning assembly 100, such as surface mount substrate 102 and reservoir housing blocks 126 and 128 and reservoir vessels (described below) may comprise chemically resistant materials such as stainless-steel alloys, or high temperature nickel alloys such as Hastelloy, as well as alloys comprising valve metal materials such as titanium, tungsten, and tantalum. In at least one implementation, high temperature chemically resistant polymers may be employed, such as, but not limited to, polyether ether ketone (PEEK) and fluoropolymers such as Teflon.

In at least one implementation, reservoir housing blocks 126 and 128, respectively, may have a generally rectilinear shape, as shown. In at least one implementation, reservoir housing blocks 126 and 128, respectively, may comprise one or more reservoir wells in which reservoir vessels may seat. In at least one implementation, reservoir housing block 126 comprises reservoir wells 130 and 132 that may extend in the z-direction (e.g., below the plane of the figure) from surface 134. In at least one implementation, reservoir housing block 128 comprises reservoir wells 136 and 138 that may extend in the z-direction from surface 135. In at least one implementation, reservoir housing blocks 126 and 128, respectively, may comprise heater cartridge wells 140. In at least one implementation, heater cartridge wells 140 may extend in the z-direction below surface 134 (e.g., below the plane of the figure) or horizontally (e.g., in the x-and/or y-directions), for example, from outer sidewalls 141 and 142 of reservoir housing blocks 126 and 128, respectively. In at least one implementation, electric heater cartridges (not shown) may seat within heater cartridge wells 140, providing heat to raise reservoir housing blocks 126 and 128 to elevated temperatures.

While heater cartridge wells 140 are shown to have a cylindrical shape in the illustrated embodiment, any suitable circumferential shape may be considered, in accordance with at least one implementation. In at least one implementation, heater cartridges may have a circular cross section, using a cylindrical geometry to heater cartridge wells 140. In at least one implementation, the number and placement of heater cartridge wells 140 may be adjusted for optimal heating of reservoir housing blocks 126 and 128. In at least one implementation, reservoir housing blocks 126 and 128 may provide heat to process gases contained within reservoir vessels and gas line tubing, maintaining them at elevated temperatures.

In at least one implementation, reservoir housing block 126 may be substantially identical to reservoir housing block 128. While the following paragraphs describe features of reservoir housing block 126, the same description may substantially apply to reservoir housing block 128. In at least one implementation, reservoir housing block 126 further comprises nonplanar sidewall 144. In at least one implementation, nonplanar sidewall 144 comprises recessed contours 146. In at least one implementation, recessed contours 146 may provide a highly nonplanar (e.g., scalloped) surface architecture for nonplanar sidewall 144.

While four recessed contours 146 are shown in the figure, any suitable number of recessed contours may be present, in accordance with at least one implementation. In at least one implementation, recessed contours 146 may conform to shapes of adjacent surface mount components 104. In at least one implementation, recessed contours 146 may comprise circular arcs. In at least one implementation, shapes of recessed contours 146 may be adapted to be complementary to adjacent surface mount components on surface mount substrate 102. In at least one implementation, recessed contours 146 follow circular arcs. The circular contours may complement the overall cylindrical shapes of adjacent surface mount components. A plan view of the component may have a generally circular profile. In at least one implementation, square boxes correspond to base flanges 148 of surface mount components 104.

In at least one implementation, recessed contours 146 may partially surround surface mount components 104, providing thermal contact from nonplanar sidewall 144 to surface mount components 104. In at least one implementation, heat transfer between process gas reservoir subassembly 118 (heated to an elevated temperature) and adjacent surface mount components 104 may be enhanced by increased contact surface area afforded by the rounded surfaces of recessed contours 146. In at least one implementation, recessed contours 146 may mechanically contact surface mount components 104 to maximize heat transfer. In at least one implementation, a small gap (e.g., 1 mm or less) may be present between recessed contours 146 and surface mount components 104. In at least one implementation, the gap may be filled with air, a liquid, or solid heat transfer material.

In at least one implementation, reservoir housing block 126 further comprises grooves 150. Grooves 150 may be recessed below the depth of recessed contours 146, as shown. Distances between grooves 150 may be any suitable distance. In at least one implementation, grooves 150 may be distributed along nonplanar sidewall 144 in any suitable pattern. In at least one implementation, grooves 150 may provide heated passages for seating and providing thermal contact to gas line tubing carrying process gases, such as risers 152.

In at least one implementation, reservoir housing block 128 comprises nonplanar sidewall 154. In at least one implementation, nonplanar sidewall 154 comprises recessed contours 156a-d. In at least one implementation, recessed contours 156a-d may comprise circular arcs, similar to recessed contours 146. In at least one implementation, recessed contours 156a-d may generally conform to the overall shape of surface mount components 104 adjacent to nonplanar sidewall 154. In at least one implementation, nonplanar sidewall 154 may also comprise grooves 158 recessed into nonplanar sidewall 154 to a depth below recessed contours 156a-d.

In at least one implementation, gas line tubing 160 may extend laterally from lateral sidewalls 122 and 124, respectively, of surface mount substrate 102. In at least one implementation, gas line tubing 160 may couple to risers 152 that extend in the z-direction above the plane of the figure. In at least one implementation, in the assembled state, risers 152 emerging from lateral sidewall 122 of surface mount substrate 102 may seat within grooves 150 within nonplanar sidewall 144. In at least one implementation, risers 152 emerging from lateral sidewall 124 of surface mount substrate 102 may seat within grooves 158 on nonplanar sidewall 154 of reservoir housing block 128. In at least one implementation, risers 152 may be heated by thermal contact with surfaces of grooves 150 and grooves 158 (described above). In at least one implementation, by virtue of grooves 150 and 158, process gases flowing within risers 152 may be preheated before reaching surface mount substrate 102.

FIG. 1B illustrates a partial cross-sectional view of process gas conditioning assembly 100, in at least one implementation. The cross-sectional view in FIG. 1B is taken along cut lines A-A′ and B-B′ made across reservoir housing blocks 126 and 128, respectively, in FIG. 1A. The cross-sectional views through reservoir housing blocks 126 and 128 illustrate reservoir wells 132 and 138, respectively, in cross section. In at least one implementation, nonplanar sidewalls 144 and 154, respectively, comprise upper planar portions 162 and 164, respectively. In at least one implementation, upper planar portions 162 and 164 may be recessed to depth d to provide access to knobs 166 on surface mount components 104. In at least one implementation, knobs 166 may be disposed on the tops of surface mount components 104, for example, to allow manual adjustments and maintenance of valves and flow controllers.

In at least one implementation, nonplanar sidewalls 144 and 154 may also comprise lower planar portions 163 and 165, respectively. In at least one implementation, lower planar portions 163 and 165 may provide clearance for positioning surface mount substrate 102 in proximity to reservoir housing blocks 126 and 128, respectively.

In at least one implementation, risers 152 are shown to extend vertically (e.g., in the z-direction) from gas line tubing 160 that extends laterally from lateral sidewalls 122 and 124. In at least one implementation, risers 152 may extend at least partially vertically within grooves 150 and 158, shown in the cross section. In at least one implementation, risers 152 may thermally contact surfaces 168 and 170 of grooves 150 and 158, enabling conductive heat transfer from process gas reservoir subassemblies 118 and 120 to gases flowing within risers 152.

In at least one implementation, reservoir wells 132 and 138 may extend vertically (e.g., in the z-direction) to depth L from surfaces 134 and 135, respectively, which may be upper surfaces of reservoir housing blocks 126 and 128, respectively. In at least one implementation, depth L may be adjusted to accommodate charge volumes (shown in FIG. 2) that may seat within reservoir wells 132 and 138.

In at least one implementation, surface mount substrate 102 comprises frontal sidewall 176 extending between lateral sidewalls 122 and 124. In at least one implementation, frontal sidewall 176 may comprise apertures 178 and 180 that may open into adjacent dual gas flow passages 108 extending below the plane of the figure. In at least one implementation, one or more heater cartridge wells 182 (e.g., two shown in the illustrated embodiment) may also extend into the interior of surface mount substrate 102 (e.g., below the plane of the figure) from frontal sidewall 176. In at least one implementation, one or more heater cartridge wells 182 may extend between subsurface flow passages that extend substantially in parallel from apertures 178 and 180 into the interior of surface mount substrate 102. In at least one implementation, depth of one or more heater cartridge wells 182 may be substantially the length of the electric heater cartridges (not shown) that are to insert within one or more heater cartridge wells 182.

FIG. 1C illustrates a side profile view in the y-z plane of an exemplary embodiment of nonplanar sidewall 144 of reservoir housing block 126 from process gas reservoir subassembly 118. It may be understood that the following description may equally apply to nonplanar sidewall 154 of reservoir housing block 128. In at least one implementation, nonplanar sidewall 144 comprises four grooves (e.g., grooves 150a, 150b, 150c, and 150d) and recessed contours 156a, 156b, 156c, and 156d. In at least one implementation, grooves 150 are shaded in dark gray to indicate deep recessing below the plane of the figure. Depth of surfaces are indicated by gray shading. In at least one implementation, surfaces coincident with the plane of the figure are unshaded (e.g., white). In at least one implementation, grooves 150 may have the greatest depth below the plane of the figure, thus have the darkest shade of gray.

In at least one implementation, grooves 150 extend at least partially vertically (e.g., in the z-direction) and may deviate from the vertical at angles such as a and b. It may be understood that the particular shape and distribution of grooves 150 shown in FIG. 1C is exemplary. Any suitable groove architecture may be adopted to suit particular designs of process gas conditioning assembly 100. In at least one implementation, grooves 150 may provide thermal contact to gas line tubing routed through grooves 150, such as risers 152 (FIGS. 1A and 1B), for example. In at least one implementation, recessed contours 156a, 156b, 156c and 156d are shown. In at least one implementation, recessed contours 156a-d may have a lighter shade of grey than grooves 150a-d to indicate that they extend to more shallow depth relative to grooves 150.

In at least one implementation, recessed contours 156a-d may follow circular, ellipsoid, or oval arcs. In at least one implementation, the arc contours may enable recessed contours 156a-d to conform to surface mount components 104 (FIG. 1A). In at least one implementation, recessed contours 156a-d may have other suitable shapes, such as rectilinear or arbitrary curvatures.

In at least one implementation, nonplanar sidewall 144 comprises upper planar portion 162 and lower planar portion.163. Upper and lower planar portions 162 and 163, respectively, may have a depth of recess (e.g., depth d shown in FIG. 1B) that provides clearance for manual access to surface mount components. In at least one implementation, upper planar portion 162 may provide clearance for access to knobs 166 on top of surface mount components 104. In at least one implementation, lower planar portion 163 may provide clearance to fit surface mount substrate 102 against reservoir housing block 126, as shown in FIG. 1B.

FIG. 1D illustrates a plan view in the x-y plane of process gas conditioning assembly 100, further comprising heated endplate 184, in accordance with at least one implementation. In at least one implementation, heated endplate 184 comprises inner face 186 and outer face 188. In at least one implementation, grooves 190 extend in the z-direction (e.g., vertically) along inner face 186. In at least one implementation, inner face 186 may be proximally adjacent or attached (e.g., by bolts) to frontal sidewall 191 of reservoir housing block 126 and to frontal sidewall 192 of reservoir housing block 128, respectively. In at least one implementation, inner face 186 may be attached (e.g., by bolts) to frontal sidewall 176 of surface mount substrate 102. In at least one implementation, grooves 190 may seat risers 194 that may extend vertically (e.g., in the z-direction), for example, from horizontally routed tubing 196. In at least one implementation, horizontally routed tubing 196 may be routed below surface mount substrate 102. Such tubing may transport inert or reactive carrier gases, for example. In at least one implementation, additional grooves (not shown) may be present in inner face 186 to seat more sections of gas line tubing. In at least one implementation, top surface 197 of heated endplate 184 may comprise heater cartridge wells 198 for housing heater cartridges (not shown). While two heater cartridge wells 198 are shown in the illustrated implementation, more heater cartridge wells may be present. In at least one implementation, heated endplate 184 may be heated to elevated temperatures by electric heating cartridges. In at least one implementation, electric heating cartridges may be regulated to provide heat to tubing seated within grooves 190 (and other such grooves). In at least one implementation, process gases flowing within risers 194, for example, may be preheated before entering surface mount substrate 102.

FIG. 1E illustrates a profile view in the x-z plane of heated endplate 184, showing grooves 190 extending vertically along inner face 186, in accordance with at least one implementation. In at least one implementation, heated endplate 184 may be attached to one or both reservoir housing blocks 126 and 128, respectively, for example, by bolting heated endplate 184 to frontal sidewalls 191 and 192, respectively (bolt holes not shown). As noted above, while two grooves 190 are shown in the illustrated implementation, more grooves may extend within inner face 186 to accommodate complex routing of gas line tubing sections that may run horizontally (e.g., in the x-direction) or obliquely along inner face 186. Openings such as apertures 199 may be present to enable insertion of heating cartridges into one or more heater cartridge wells 182 in frontal sidewall 176 of surface mount substrate 102 (shown in FIG. 1B), for example.

FIG. 2 illustrates an exploded 3D view of a complete process gas reservoir subassembly 118, comprising reservoir yoke 200 and reservoir housing block 126, in accordance with at least one implementation. In at least one implementation, reservoir yoke 200 may comprise one or more charge volume cannisters (e.g., reservoir vessels) 202 and 204. In at least one implementation, charge volume cannisters 202 and 204 may seat within reservoir wells 130 and 132, respectively. While in the illustrated implementation two charge volume canisters 202 and 204 are shown, any suitable number of charge volume reservoirs may be accommodated by reservoir housing block 126. In at least one implementation, reservoir yoke 200 may comprise a single charge volume cannister. In at least one implementation, reservoir yoke 200 may comprise three or more separate charge volume cannisters. In at least one implementation, a charge volume cannister may have any suitable shape and volume. In at least one implementation, charge volume cannisters 202 and 204 may be generally cylindrical and individually contain up to 500 milliliters (ml). Other suitable shapes and volumes may be considered.

In at least one implementation, reservoir yoke 200 comprises manifold 206 at the top of reservoir yoke 200. In at least one implementation, charge volume cannisters 202 and 204 may be mechanically coupled to manifold 206 by various means. Manifold 206 may provide rigid mechanical support for charge volume cannisters 202 and 204. In at least one implementation, charge volume cannisters 202 and 204 may be fluidically coupled together by passage 208. In at least one implementation, passage 208 may extend within manifold 206 as illustrated. Hidden lines within the body of manifold 206 indicate that passage 208 may be a subsurface feature. In at least one implementation, passage 208 may enable the combining of process gases contained with charge volume cannisters 202 and 204. In at least one implementation, individual charge volume cannisters 202 and 204 may hold approximately 500 milliliters (ml). Passage 208 may enable combining the process gas charges held within charge volume cannisters 202 and 204 to make a total charge volume of 1000 ml. In at least one implementation, passage 208 may be omitted or valved, enabling charge volume cannisters 202 and 204 to remain entirely separate. In at least one implementation, process gas charges contained within charge volume cannisters 202 and 204 may remain separated until mixed within surface mount substrate 102, for example.

In at least one implementation, tubing 210 may extend from passage 208. For clarity, a stub portion of tubing 210 is shown in the figure. It may be understood that tubing 210 may be a longer section of tubing coupling charge volume cannisters 202 and 204 to surface mount substrate 102, for example. In at least one implementation, tubing 210 may provide an outlet flow path for the discharge of process gases contained within charge volume cannisters 202 and 204. In at least one implementation, tubing 210 may interconnect charge volume cannisters 202 and/or 204 with one of risers 152, for example, leading to surface mount substrate 102.

Referring to reservoir housing block 126, grooves 150 (e.g., grooves 150a, 150b, 150c and 150d) are shown partially. In at least one implementation, a portion of nonplanar sidewall 144 is removed in the figure to generalize the nonplanar architecture. For example, the vertical dashed lines extending from the upper portions of grooves 150 may indicate at least partial vertical extension of grooves 150 along nonplanar sidewall 144. A single recessed contour 156 is shown. Shapes, dimensions, and distributions of grooves 150 and recessed contours 156a-d may suit particular design requirements. In at least one implementation, upper and lower planar portions 162 and 163, respectively, of nonplanar sidewall 144 may be recessed to a suitable depth to accommodate surface mount substrate 102 and surface mount components 104.

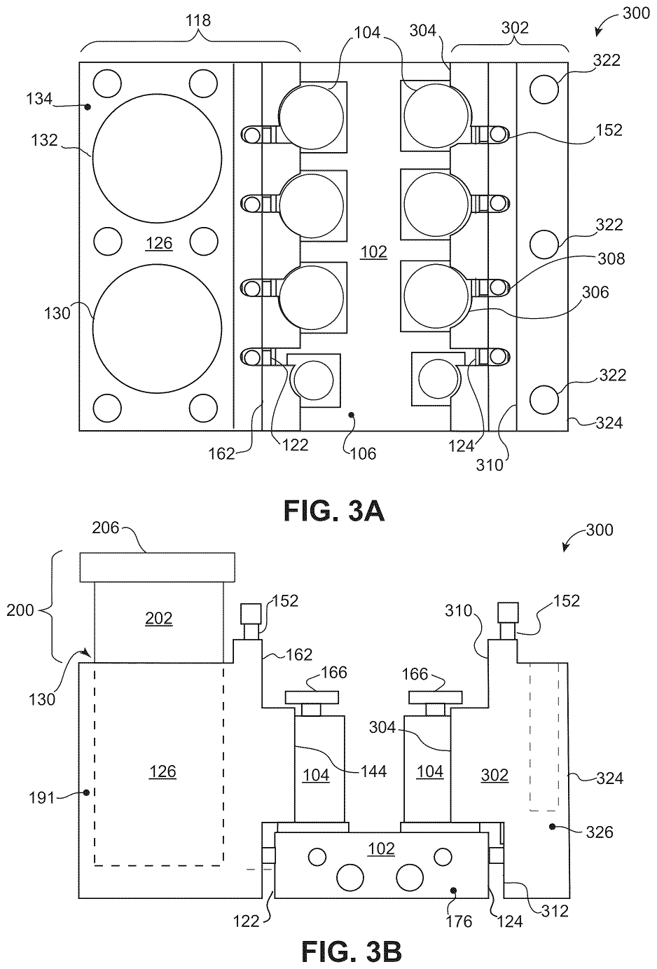

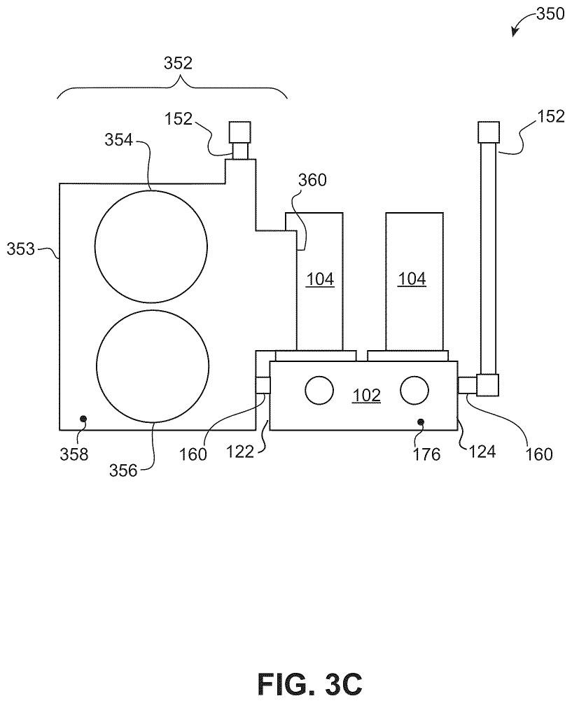

FIG. 3A illustrates a plan view in the x-y plane of process gas conditioning assembly 300, in accordance with at least one implementation. In at least one implementation, process gas conditioning assembly 300 comprises process gas reservoir subassembly 118 adjacent to lateral sidewall 122 of surface mount substrate 102. In at least one implementation, process gas reservoir subassembly 118 comprises reservoir housing block 126. In at least one implementation, process gas conditioning assembly 300 further comprises heated panel 302, adjacent to opposing lateral sidewall 124 of surface mount substrate 102. In at least one implementation, heated panel 302 comprises nonplanar sidewall 304. In at least one implementation, nonplanar sidewall 304 may be substantially identical to nonplanar sidewall 154. In at least one implementation, heated panel 302 may be substantially similar to reservoir housing block 128 without reservoir wells (e.g., reservoir wells 136 and 138). In at least one implementation, heated panel 302 may be employed as an optional modular component of process gas conditioning assembly 300. In at least one implementation, heated panel 302 may be interchangeable with reservoir housing block 126 or 128. In some implementations, heated panel 302 may be interchanged with reservoir housing block 128, also a modular component. In at least one implementation, interchangeability of modules may afford rapid conversion of process gas conditioning assembly 100 to process gas conditioning assembly 300. In at least one implementation, a reservoir bank afforded by process gas conditioning assembly 300 may offer a more efficient and compact installation.

In at least one implementation, heated panel 302 may comprise stainless steel, Hastelloy, or another suitable high temperature and chemically resistant material. In at least one implementation, heated panel 302 may be machined from a single stock block of stainless steel or Hastelloy, for example, or fabricated by an additive process such as 3D printing. In at least one implementation, heated panel 302 may comprise nonplanar sidewall 304. In at least one implementation, nonplanar sidewall 304 may comprise recessed contour and groove features that are substantially identical both in form and function to those of reservoir housing block 128.

In at least one implementation, nonplanar sidewall 304 comprises recessed contours 306. In at least one implementation, recessed contours 306 may be similar or substantially identical to recessed contours 156a-d of reservoir housing block 128. As shown in FIG. 3A, recessed contours 306 may generally conform to the shape of surface mount components 104, as described above. In at least one implementation, recessed contours 306 may comprise circular arcs that enable efficient thermal contact between surface mount components 104 and recessed contours 306. In at least one implementation, the circular arcs of recessed contours 306 may be conformal to surface mount components 104, which may generally have cylindrical shapes. In at least one implementation, grooves 308 may be recessed into nonplanar sidewall 304 below the depth of recessed contours 306. In at least one implementation, grooves 308 may be substantially identical to grooves 158 in nonplanar sidewall 154 of reservoir housing block 128. In at least one implementation, grooves 308 may provide thermal contact for risers 152, for example. In at least one implementation, upper planar portion 310 of nonplanar sidewall 304 may be recessed to provide clearance for manual manipulation of knobs 166, for example (see FIG. 3B). In at least one implementation, heated panel 302 may comprise heater cartridge wells 322 to provide heat to heated panel 302. Any suitable number of heater cartridge wells 322 may be employed. In at least one implementation, heater cartridge wells 322 may be vertically oriented, as shown, and/or horizontally oriented through outer sidewall 324 or frontal sidewall 326.

FIG. 3B illustrates a profile view in the x-z plane of process gas conditioning assembly 300, in accordance with at least one implementation. In at least one implementation, reservoir housing block 126 is shown with accompanying reservoir yoke 200. In at least one implementation, charge volume cannister 202 is shown partially withdrawn from reservoir well 130. In comparison to process gas reservoir subassembly 118, heated panel 302 may provide equally efficient heating of surface mount components 104 and gas line tubing 160 and risers 152.

In at least one implementation, heated panel 302 has a smaller lateral footprint than reservoir housing block 128. Because of the smaller footprint afforded by heated panel 302, process gas conditioning assembly 300 may have a more compact overall footprint in comparison to process gas conditioning assembly 100, in accordance with at least one implementation. In at least one implementation, process gas conditioning assembly 300 may have 60% or less of the footprint of process gas conditioning assembly 100. In at least one implementation, more compact configuration of process gas conditioning assembly 300 may suit process tool installations where space may be limited for placement of process gas conditioning and distribution equipment. In at least one implementation, a distance between lower planar portion 312 of heated panel 302 and lateral sidewall 124 of surface mount substrate 102 may be adjusted to further reduce the footprint.

In at least one implementation, reservoir housing block 126 may be exchanged for a second heated panel that is substantially identical to heated panel 302. In at least one implementation, charge volume cannisters 202 and 204 or direct process gas sources may be heated by remote means if so desired and may be remotely coupled to surface mount substrate 102.

FIG. 3C illustrates a profile view in the x-z plane of process gas conditioning assembly 350, similar to process gas conditioning assembly 300, in accordance with at least one implementation. In at least one implementation, process gas conditioning assembly 350 comprises process gas reservoir subassembly 352. In at least one implementation, process gas reservoir subassembly 352 comprises reservoir housing block 353 and a horizontally (e.g., in the x or y-direction of the figure) oriented reservoir yoke (e.g., reservoir yoke 200 comprising charge volume cannisters 202 and 204, FIG. 2). In at least one implementation, reservoir yoke and charge volume cannisters are omitted for clarity. In at least one implementation, reservoir wells 354 and 356 within reservoir housing block 353 may extend horizontally (in the y-direction of the figure, below the plane of the figure) from sidewall 358. In at least one implementation, horizontal orientation of reservoir wells 354 and 356 may enable convenient access to process charge volume cannisters (not shown) housed within reservoir housing block 353. In at least one implementation, in a confined space, vertically oriented charge volumes that are top-accessible may be difficult to service without dismantling of entire assembly. In at least one implementation, horizontally oriented charge volume cannisters may be more convenient to access from the side in such situations.

In at least one implementation, reservoir housing block 353 comprises nonplanar sidewall 360. In at least one implementation, nonplanar sidewall 360 is substantially the same as nonplanar sidewall 144 of reservoir housing block 126 illustrated in FIGS. 1A and 1B. In at least one implementation, nonplanar sidewall 360 may comprise recessed contours, such as recessed contours 156a-d and grooves, such as grooves 158a-d.

In at least one implementation, process gas conditioning assembly 350 may have a modular architecture, where one process gas reservoir subassembly 352 or two such subassemblies may be assembled with surface mount substrate 102. In at least one implementation, a single process gas reservoir subassembly 352 is shown adjacent to lateral sidewall 122 of surface mount substrate 102. In at least one implementation, a second process gas reservoir subassembly (e.g., similar to or substantially identical to process gas reservoir subassembly 352) may be assembled adjacent to lateral sidewall 124 (e.g., flanking surface mount substrate 102 on the right-hand side of the figure). In at least one implementation, surface mount components 104 on the right-hand side of surface mount substrate 102 are exposed, as are risers 152 extending from gas line tubing 160. In at least one implementation, a second heated panel, such as heated panel 302, may be placed adjacent to lateral sidewall 124 of surface mount substrate 102 to complete assembly in a modular fashion.

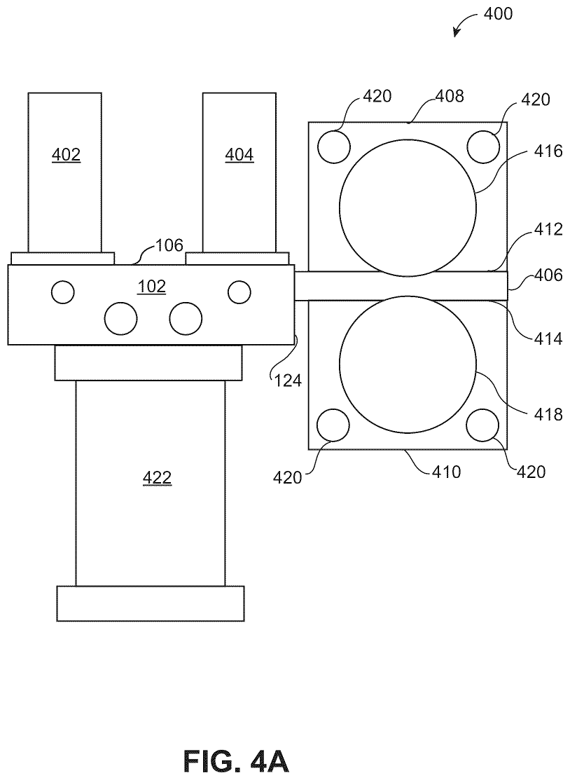

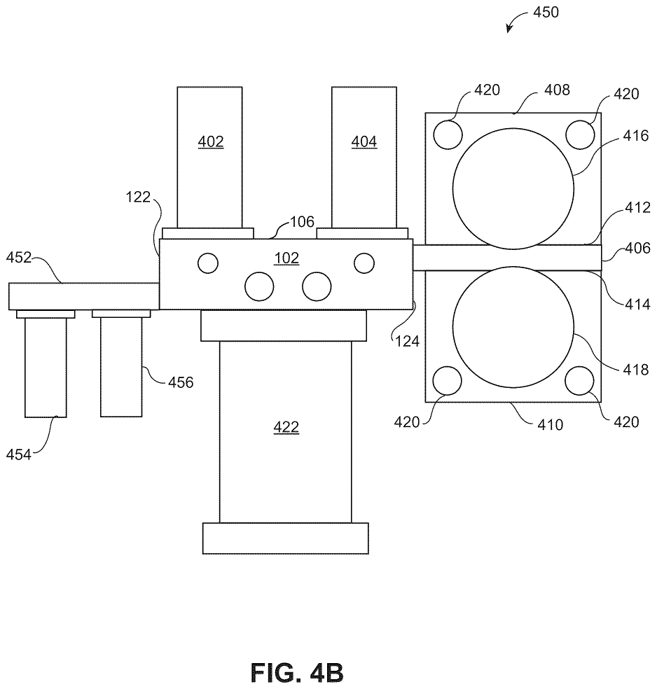

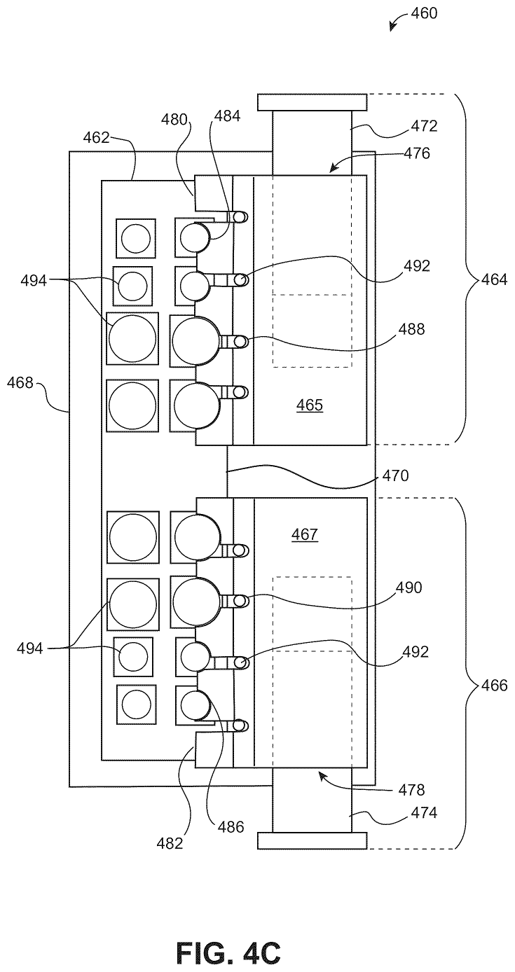

FIG. 4A illustrates a profile view in the x-z plane of process gas conditioning assembly 400, according to at least one implementation. In at least one implementation, process gas conditioning assembly 400 comprises surface mount substrate 102. In at least one implementation, surface mount components 402 and 404 are shown mounted on surface 106 of surface mount substrate 102. In at least one implementation, process gas conditioning assembly 400 further comprises a platform 406 extending laterally from lateral sidewall 124 of surface mount substrate 102. In at least one implementation, platform 406 may support reservoir housing block 408 and reservoir housing block 410, to provide thermal contact. In at least one implementation, reservoir housing blocks 408 and 410 may be positioned on upper surface 412 and lower surface 414, respectively, of platform 406. In at least one implementation, charge volume cannisters (not shown) may be inserted into reservoir wells 416 and 418 within reservoir housing blocks 408 and 410. In at least one implementation, reservoir housing blocks 408 and 410 may comprise heater cartridge wells 420. In at least one implementation, electric heater cartridges housed within heater cartridge wells 420 may provide heat for process gases contained within reservoir housing blocks 408 and 410. In at least one implementation, process gas conditioning assembly 400 may provide a more compact form factor than previously described embodiments (e.g., process gas conditioning assemblies 100 and 300).

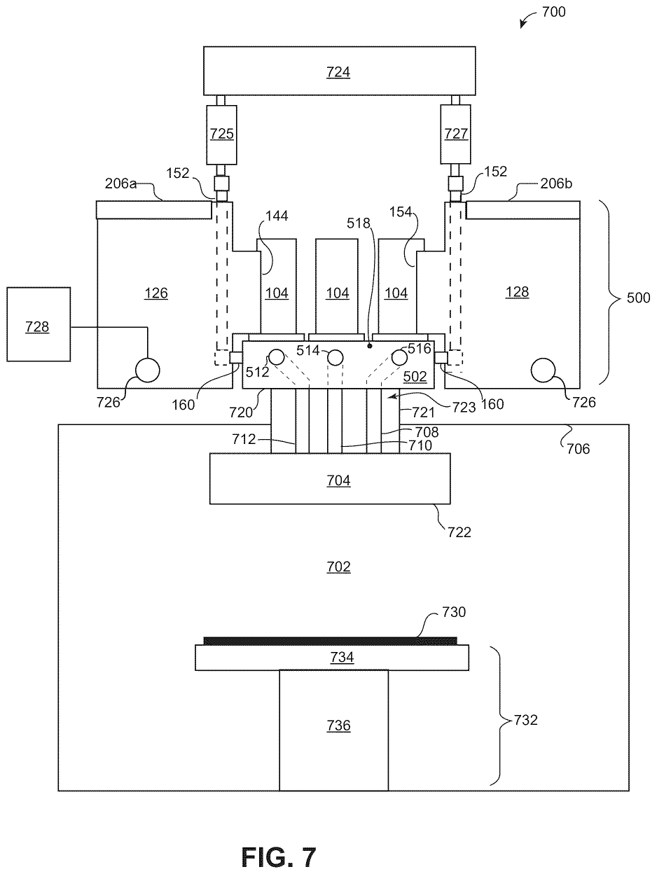

In at least one implementation, showerhead inlet adapter 422 may be included in process gas conditioning assembly 400. In at least one implementation, showerhead inlet adapter 422 may provide a pedestal-like structure to support process gas conditioning assembly 400. In at least one implementation, showerhead inlet adapter 422 may provide housing for tubing routed between process gas conditioning assembly 400 and a showerhead within a chemical vapor deposition (or atomic layer deposition) process chamber of a semiconductor process tool (e.g., shown in FIG. 7). In at least one implementation, showerhead inlet adapter 422 comprises heater cartridges for heating tubing routed within.

FIG. 4B illustrates a profile view in the x-z plane of process gas conditioning assembly 450, in accordance with at least one implementation. In at least one implementation, process gas conditioning assembly 450 may comprise process gas conditioning assembly 400 and minor substrate 452, extending laterally from lateral sidewall 122 of (main) surface mount substrate 102. In at least one implementation, minor substrate 452 may provide a secondary gas flow substrate, similar in construction to surface mount substrate 102, for example, to accommodate surface mount components 454 and 456. Surface mount components 454 and 456 may be physically smaller than surface mount components 402 and 404. In at least one implementation, smaller size of the surface mount components mounted on minor substrate 452 may enable more efficient handling of trickle flows of carrier gases, for example. In at least one implementation, other components, such as platform 406, reservoir housing blocks 408 and 410 may be substantially the same as described for process gas conditioning assembly 400.

FIG. 4C illustrates a plan view in the x-y plane of process gas conditioning assembly 460, in accordance with at least one implementation. In at least one implementation, process gas conditioning assembly 460 comprises surface mount substrate 462, and process gas reservoir subassemblies 464 and 466. In at least one implementation, process gas reservoir subassemblies 464 and 466, as well as surface mount substrate 462 may be mounted on support plate 468. In at least one implementation, process gas reservoir subassemblies 464 and 466 comprise blocks 465 and 467, respectively. In at least one implementation, both adjacent to sidewall 470 of surface mount substrate 462, displaced from one another along sidewall 470. In at least one implementation, process gas reservoir subassemblies 464 and 466 further comprise charge volume reservoirs 472 and 474, respectively, seated within reservoir wells 476 and 478, respectively (arrows pointing into opening of reservoir wells delineated by hidden lines). In at least one implementation, charge volume reservoirs 472 and 474 are shown partially seated within reservoir wells 476 and 478, respectively.

In at least one implementation, reservoir wells 476 and 478 are oriented parallel to sidewall 470 of surface mount substrate 462. In at least one implementation, reservoir wells 476 and 478 extend along the y-direction of the figure, substantially parallel to sidewall 470. In at least one implementation, a parallel rather than an orthogonal orientation of reservoir wells 476 and 478 may enable a more compact architecture of process gas conditioning assembly 460.

In at least one implementation, blocks 465 and 467 comprise nonplanar sidewalls 480 and 482, respectively. In at least one implementation, nonplanar sidewalls 480 and 482 comprise pluralities of recessed contours 484 and 486, respectively, as well as pluralities of grooves 488 and 490, respectively. In at least one implementation, individual grooves 488 and 490 cut into nonplanar sidewalls 480 and 482 to a depth extending below the depth of recessed contours 484 and 486. In at least one implementation, grooves 488 and 490 may cut through recessed contours 484 and 486, as shown, to extend to a predetermined distance from nonplanar sidewall 482.

In at least one implementation, a plurality of gas line tubing sections comprising risers 492 (extending in the z-direction of the figure) may extend laterally from surface mount substrate 462. In at least one implementation, the depth of grooves 488 and 490 from nonplanar sidewall 480 and 482, respectively, may be predetermined to accommodate the lateral displacement of risers 492 from sidewall 470 of surface mount substrate 462. Risers 492 may extend along grooves 488 and 490, which may be at least partially oriented vertically (e.g., in the z-direction of the figure). In at least one implementation, risers 492 may be in thermal contact with walls of grooves 488 and 490. In at least one implementation, thermal contact may be direct mechanical contact between walls of risers 492 and walls of grooves 488 and 490. In at least one implementation, risers 492 and grooves 488 and 490 may not have direct mechanical contact. In at least one implementation, a small gap (e.g., 1 mm or less) may be present between risers 492 and grooves 488 and 490.

In at least one implementation, recessed contours 484 and 486 may comprise circular arcs that may partially surround surface mount components 494 on surface mount substrate 462. In at least one implementation, recessed contours 484 and 486 may be in thermal contact with surface mount components 494, as described above. In at least one implementation, walls of recessed contours 484 and 486 may be in direct mechanical contact with surface mount components 494. In at least one implementation, a gap (1 mm or less) may be present between walls of recessed contours and surfaces of surface mount components 494.

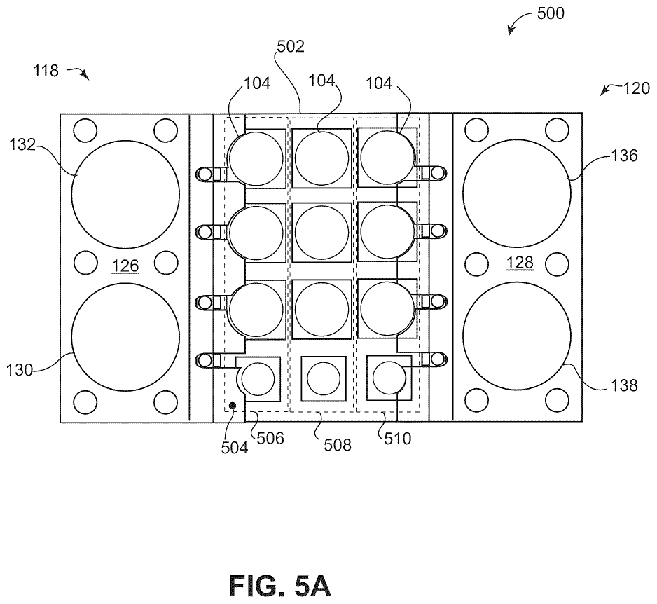

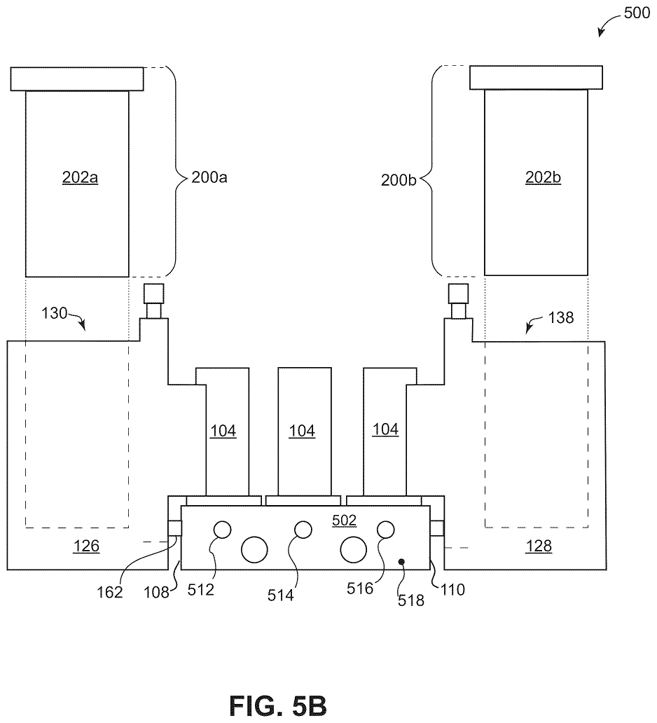

FIG. 5A illustrates a plan view in the x-y plane of process gas conditioning assembly 500, according to at least one implementation. In at least one implementation, process gas conditioning assembly 500 comprises surface mount substrate 502 flanked by process gas reservoir subassemblies 118 and 120. In at least one implementation, surface mount substrate 502 comprises three gas flow passages (not shown) extending below surface 504. In at least one implementation, individual subsurface flow passages may be fluidically coupled to surface mount components 104, respectively. In at least one implementation, surface mount components 104 are grouped into three columns 506, 508, and 510 (delineated by dashed boxes) that may be aligned to subsurface gas flow passages.

With the exception of surface mount substrate 502, the description for process gas conditioning assembly 100 given above may substantially apply to process gas conditioning assembly 500. In at least one implementation, process gas reservoir subassemblies 118 and 120 are substantially as described above and shown in FIGS. 1A and 1B. In at least one implementation, surface mount substrate 502, having a triple flow passage architecture, may be an expansion of surface mount substrate 102, comprising a dual flow passage architecture. In at least one implementation, gas conditioning substrates may comprise four or more process gas flow passages. In at least one implementation, surface mount substrates 102 and 502, respectively, may be interchangeable. In at least one implementation, surface mount substrate 502 (e.g., as a triple flow passage substrate module) may be exchanged with surface mount substrate 102 (e.g., a dual flow passage substrate module), enabling transformation of process gas conditioning assembly 100 or 300 to process gas conditioning assembly 500.

In at least one implementation, surface mount substrate 502, comprising three subsurface process gas flow passages, may be employed for implementations where two precursor gases are mixed with a third gas stream. In at least one implementation, the third gas stream may comprise a reactive process gas. In at least one implementation, the third stream may comprise a reducing mixture containing hydrazine, hydrogen and/or ammonia. In at least one implementation, the mixture may also be oxidizing, comprising water vapor, oxygen, ozone, nitrous oxide, etc.

In at least one implementation, process gas conditioning assembly 500 may further comprise a heated endplate, such as heated endplate 184 shown in FIG. 1E. In at least one implementation, a heated panel, such as heated panel 302 shown in FIGS. 3A and 3B, may be exchanged for one or both of process gas reservoir subassemblies 118 and/or 120.

FIG. 5B illustrates an exploded profile view in the x-z plane of process gas conditioning assembly 500, comprising surface mount substrate 502, and process gas reservoir subassemblies 118 and 120, in accordance with at least one implementation. In at least one implementation, process gas reservoir subassemblies 118 and 120 may comprise reservoir yoke 200a and reservoir yoke 200b, respectively. In at least one implementation, reservoir yokes 200a and 200b may be substantially similar to process gas reservoir subassembly 118 as shown in FIG. 2 and described above. In at least one implementation, reservoir yokes 200a and 200b comprise charge volume cannisters 202a and 202b, respectively.

In at least one implementation, charge volume cannisters 202a and 202b may seat within reservoir wells 130 and 138, not shown) in reservoir housing block 126. In at least one implementation, charge volume cannisters 202a and 202b may seat within reservoir wells 130 and reservoir well 138. In at least one implementation, the vertical extent of reservoir wells 130 and 138 are indicated by the hidden lines in reservoir housing blocks 126 and 128.

FIG. 5B also shows terminal ports 512, 514, and 516 in frontal sidewall 518 of surface mount substrate 502, in accordance with at least one implementation. In at least one implementation, terminal ports 512-516 may open to the three subsurface process gas flow passages with surface mount substrate 502. In at least one implementation, terminal ports 512-516 may be entry points for process gas lines that transport inert carrier gases such as argon into the subsurface flow passages, for example.

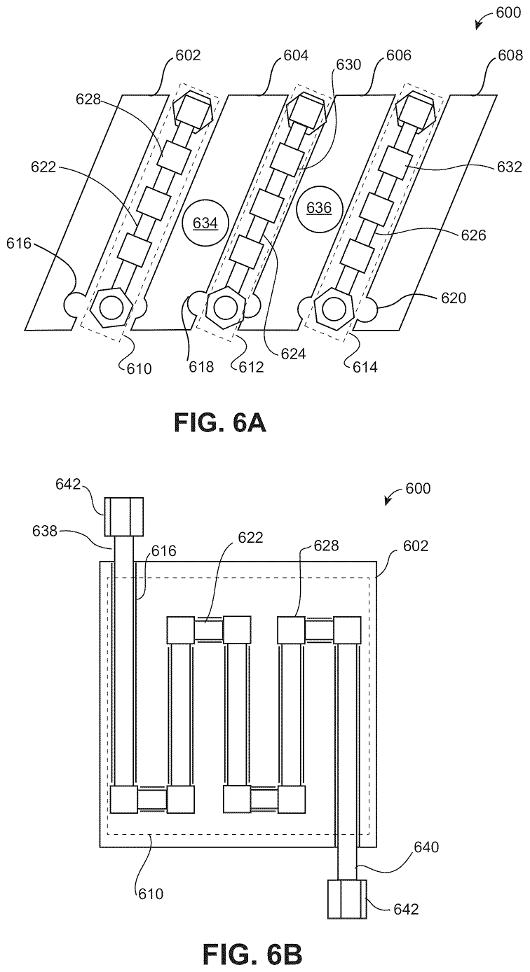

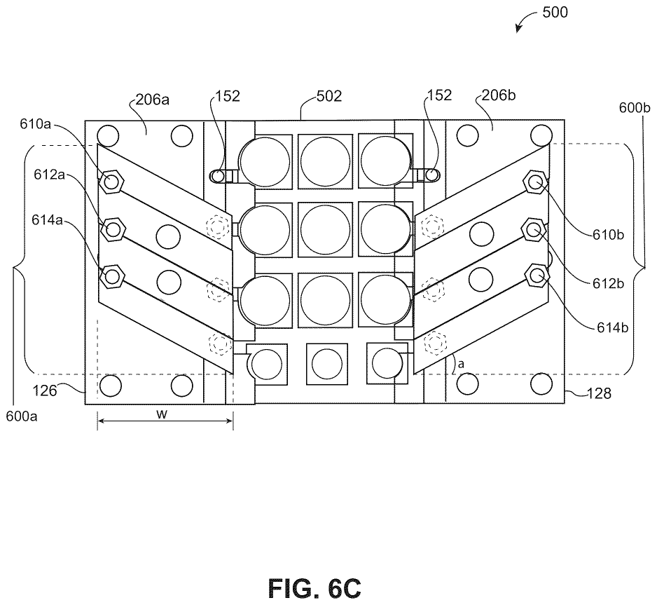

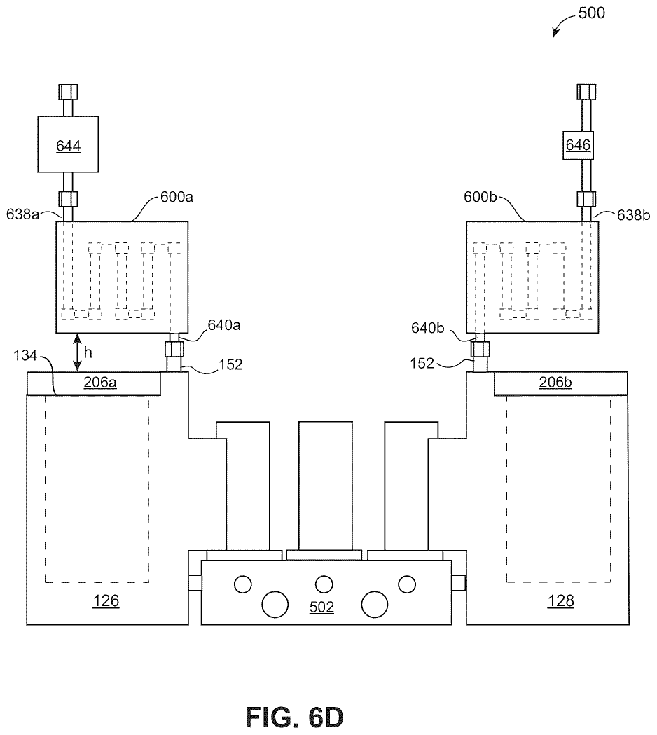

FIG. 6A illustrates an exploded plan view in the x-y plane of preheater assembly 600, comprising two or more plates arranged in a stack assembly, in accordance with at least one implementation. In at least one implementation, preheater assembly 600 may be a component of process gas conditioning assembly 100 or 500. In at least one implementation, preheater assembly 600 may be employed to preheat certain process gases prior to introduction of the process gases to the surface mount substrate component (e.g., surface mount substrate 502) of the process gas conditioning assembly. In at least one implementation, preheater assembly comprises plates 602, 604, 606, and 608. In at least one implementation, plates 602-608 may be arranged in a stack assembly. In at least one implementation, plates 602-608 may provide thermal mass for transfer of heat to gas line tubing sections passing through preheater assembly 600. In at least one implementation, gas line tubing sections, described below, may pass between adjacent plates. In at least one implementation, plates 602-608 may comprise a thermally conductive material such as, but not limited to, aluminum, copper, brass, or stainless steel. In at least one implementation, plates 602-608 may have a rhomboid cross section, as shown in the plan view. In at least one implementation, the rhomboid cross section of plates 602-808 may impart a rhomboidal footprint to preheater assembly 600. In at least one implementation, the rhomboidal shape may minimize the lateral footprint of preheater assembly 600.

In the exploded view of FIG. 6A, plates 602-608 are separated to illustrate gas line tubing sections 610, 612, and 614. In at least one implementation, gas line tubing sections 610, 612, and 614, delineated by the dashed boxes, may be positioned between pairs of individual plates. In at least one implementation, gas line tubing section 610 is positioned between plates 602 and 604. In at least one implementation, gas line tubing section 612 may be positioned between plates 604 and 606, and gas line tubing section 612 may be positioned between plates 606 and 608. It is understood that gas line tubing sections 610-614 are normally embedded within plates 602-608 in the assembled state. In at least one implementation, some of plates 602, 604, 606, and 608 may comprise grooves 616, 618, and 620 for embedding gas line tubing sections 610, 612, and 614, respectively.

In at least one implementation, gas line tubing sections 610-614 may comprise multiple subsections 622, 624, and 626, respectively. In at least one implementation, gas line tubing sections 616-620 may be interconnected in a serpentine configuration by 90° elbows 628, 630, and 632, for example. In at least one implementation, a serpentine configuration of gas line tubing sections 610-614 may maximize thermal contact between plates 602-608 and gas line tubing sections 610-614 for a compact volume of preheater assembly 600. While the plan view of FIG. 6A shows some interconnecting gas line tubing sections extending parallel to the plane of the figure, it is understood that some sections extend orthogonally (e.g., below the plane of the figure) with respect to the parallel sections. An example of a serpentine arrangement of interconnecting gas line tubing sections is shown in FIG. 6B. In at least one implementation, plates 602-608 may have a rhomboidal cross section in at least one plane (e.g., the x-y plane). In at least one implementation, a rhomboidal cross section of preheater assembly 600 may provide a compact footprint while providing maximal thermal contact with gas line tubing sections 610-614.

In at least one implementation, gas line tubing sections 610-614 may be sections of separate and independent gas transport flow paths that route processes gases to the process gas conditioning assembly in separate lines.

In at least one implementation, plates 604 and 606 are adjacent in the middle portion of the stack assembly comprise heater cartridge wells 634 and 636, respectively, for seating of heater cartridges. In at least one implementation, plates 604 and 606 are modular so that preheater assembly 600 may be built out to custom sizes for accommodation of larger or smaller numbers of gas line tubing sections. In at least one implementation, plates 604 and 606 may be at least two middle plates that are substantially identical. Middle plates (e.g., plates 604 and 606) may be positioned between “bookend” or “end cap” plates 602 and 608. Two middle plates may and two end cap plates, as shown in FIG. 6A, may accommodate three individual gas lines. In at least one implementation, middle plates (e.g., plates 602 and 608) may be substantially identical to each other but have a different design than plates 604 and 606. While a total of four plates are included in preheater assembly 600 shown in the illustrated embodiment, any suitable number of middle plates similar or identical to plates 604 and 606 may be included. In at least one implementation, six plates within the stack assembly (e.g., four middle plates between two end cap plates) may enable five gas lines to pass through preheater assembly 600. In at least one implementation, modularity of preheater assembly 600 may enable more plates to be added as needed. In at least one implementation, larger plate numbers enable larger numbers of individual gas line tubing sections to pass through preheater assembly 600. In at least one implementation, a stack of N plates may accommodate N−1 individual gas lines.

In at least one implementation, heater cartridges may seat within heater cartridge wells 634 and 636 to provide heat to gas line tubing sections 610-614. In at least one implementation, suitable numbers of heater cartridges may be employed for providing adequate heat to the flowing gases within the gas lines sections passing through preheater assembly 600.

FIG. 6B illustrates a cross sectional view in the y-z plane of preheater assembly 600, in accordance with at least one implementation. The illustrated implementation shows gas line tubing section 610 (delineated by dashed box) as a single gas line section adjacent to and abutted against plate 602. While plate 602 is shown in the illustrated implementation, it may be understood that the other plates 604, 606, and 608 and adjacent gas line tubing sections 612 and 614 within the stack of preheater assembly 600 may be equally shown. In at least one implementation, gas line tubing section 610 may be seated within groove 616. In at least one implementation, groove 616 may comprise multiple orthogonal segments, as shown, that follow the serpentine configuration of gas line tubing section 610. In at least one implementation, upper tubing stub 638 and lower tubing stub 640 may provide interconnections through compression fittings 642 to external gas line tubing.

FIG. 6C illustrates a plan view in the x-y plane of process gas conditioning assembly 500 comprising preheater assemblies 600a and 600b, in accordance with at least one implementation. In at least one implementation, process gas conditioning assembly 500 comprises dual preheater assemblies (e.g., preheater assemblies 600a and 600b) as shown. In at least one implementation, process gas conditioning assembly 500 may comprise a single preheater assembly (e.g., either preheater assembly 600a or 600b). In at least one implementation, preheater assembly 600a is positioned over manifold 206a, mounted on the upper surface of reservoir housing block 126.

In at least one implementation, preheater assemblies 600a and 600b may be coupled to one or more risers 152 adjacent to reservoir housing blocks 126 and 128, respectively. In at least one implementation, gas line tubing sections 610a, 612a, and 614a may be coupled to risers 152 extending from surface mount substrate 502 (e.g., left side) through compression fittings 642 on the terminals of lower tubing stubs 640 (indicated by hidden lines in FIG. 6C; see FIGS. 6B and 6D). In at least one implementation, preheater assembly 600a may be vertically offset from manifold 206a on the upper surface (e.g., surface 134) of reservoir housing block 126 by approximately the length of lower tubing stub 640, as shown in FIG. 6D.

In at least one implementation, preheater assembly 600b may be positioned over manifold 206b on reservoir housing block 128. In at least one implementation, gas line tubing sections 610b, 612b, and 614b may be coupled to risers 152 extending from surface mount substrate 502 (e.g., right side) adjacent to reservoir housing block 128. In at least one implementation, lower tubing stubs 640 (indicated by hidden lines) on preheater assembly 600b may also be vertically offset from manifold 206b by a similar or substantially same offset distance of preheater assembly 600a.

In at least one implementation, preheater assemblies 600a and 600b may have rhomboidal cross sections in at least one plane (e.g., the x-y plane as shown). As noted above, the rhomboidal shape of preheater assemblies 600a and 600b may limit the width w (e.g., lateral extent in the x-direction of the figure) of preheater assemblies 600a and 600b. In at least one implementation, thermal contact between inner walls of preheater assembly 600 and gas line tubing sections 610-614 may be maximized by optimizing the rhomboidal angle α. In at least one implementation, angle α may be adjusted to maximize the total length of gas line tubing sections 610-614 in contact with preheater stack plates (e.g., plates 602-608 in FIG. 6A). Concurrently, width w of preheater assemblies 600a and 600b may be minimized by optimization of angle α.

FIG. 6D illustrates a profile view in the x-z plane of process gas conditioning assembly 500, comprising preheater assemblies 600a and 600b as shown in FIG. 6C. FIG. 6D shows preheater assemblies 600a and 600b in vertical relation to reservoir housing blocks 126 and 128, respectively, in accordance with at least one implementation. In at least one implementation, gas line tubing sections (e.g., gas line tubing sections 610-614) are indicated by hidden lines within preheater assemblies 600a and 600b. In at least one implementation, gas line tubing sections may be embedded within preheater assemblies 600a and 600b, for example in a serpentine formation as shown. In at least one implementation, preheater assemblies 600a and 600b may be coupled to process gas conditioning assembly through lower tubing stubs 640a and 640b, coupled to risers 152 on opposing sides of surface mount substrate 502. In at least one implementation, preheater assemblies 600a and 600b may be vertically offset by a height h from manifolds 206a and 206b, mounted on upper surfaces of reservoir housing blocks 126 and 128. In at least one implementation, height h may depend substantially on the length of lower tubing stubs 640a and 640b.

In at least one implementation, external gas lines coupled to process gas conditioning assembly 500 may include foreline heater jacket 644 for heating some process gases (e.g., hydrogen). In at least one implementation, foreline heater jacket 644 may be in line with preheater assembly 600a and/or 600b, for example, coupled to upper tubing stubs 638a and 638b. In at least one implementation, foreline heater jacket 644 may provide additional heating. In at least one implementation, one or more heated valve 646 may be included in the process gas external flow path.

FIG. 7 illustrates a cross sectional view in the x-z plane of semiconductor process tool 700 comprising process gas conditioning assembly 500, in accordance with at least one implementation. It may be understood that while process gas conditioning assembly 500 (shown in FIGS. 5A and 5B) is shown in the example, other disclosed implementations of the process gas conditioning assembly, such as process gas conditioning assembly 100 and process gas conditioning assembly 300 may be equally employed in the example. In at least one implementation, semiconductor process tool 700 comprises vacuum chamber 702. In at least one implementation, showerhead 704 is disposed within vacuum chamber 702 near upper wall 706. In at least one implementation, process gas conditioning assembly 500 may be fluidically coupled to showerhead 704 through conduit 708, conduit 710, and conduit 712 that extend through showerhead inlet adapter 721. In at least one implementation, showerhead inlet adapter 721 may also provide mechanical support for process gas conditioning assembly 500 as well as housing for conduits 708, 710, and 712.

In the illustrated embodiment, conduits 708 and 710 extend from lower surface 720 of surface mount substrate 502. In at least one implementation, conduits 708, 710, and 712 may be fluidically coupled to three subsurface gas flow passages within surface mount substrate 502. In at least one implementation, conduits 708-712 may extend through cavity 723 (e.g., a tubular cavity) of showerhead inlet adapter 721, as shown. In at least one implementation, individual conduits 708-712 may terminate at an annular aperture (not shown) that opens into chambers of showerhead 704. In at least one implementation, three subsurface process gas flow passages may be coupled to terminal ports 512, 514, and 516 on frontal sidewall 518 of surface mount substrate 502. In at least one implementation, terminal ports 512, 514, and 516 may be coupled to gas line tubing that transport inert carrier gases such as argon or nitrogen to the subsurface gas flow passages in surface mount substrate 502. In at least one implementation, interior coupling between conduits 708, 710, and 712 and inner flow passages in surface mount substrate 502 is indicated by the hidden lines extending between lower surface 720 of surface mount substrate 502 and terminal ports 512, 514, and 516, respectively. In at least one implementation, conduits 708 and 712 may respectively transport a first preconditioned precursor process gas (e.g., a vapor of a first precursor substance) and a second preconditioned precursor process gas (e.g., a vapor of a second precursor substance) to showerhead 704. In at least one implementation, conduit 710 may transport a third preconditioned process gas as a vapor or a reactive gas to showerhead 704. In at least one implementation, the three separate process gasses transported by conduits 708-712 may mix within showerhead 704 or issue separately through faceplate 722 of showerhead 704 into vacuum chamber 702.

In at least one implementation, showerhead 704 may be operational to distribute preconditioned process gases into vacuum chamber 702. In at least one implementation, process gases may be preconditioned by passage through process gas conditioning assembly 500. In at least one implementation, during operation, for example, the first and second process gases may be held under pressure within charge volume reservoirs (e.g., charge volume cannisters 202a and 202b carried by reservoir yokes 200a and 200b as shown in FIG. 5B). In at least one implementation, manifolds 206a and 206b of reservoir yokes 200a and 200b, respectively, are shown seated on reservoir housing blocks 126 and 128, respectively. In at least one implementation, charge volume cannisters 202a and 202b are inserted within reservoir wells 130 and 138 in reservoir housing blocks 126 and 128. In at least one implementation, a third process gas (e.g., an inert or reactive carrier gas) may be introduced into a subsurface flow passage within surface mount substrate 102 through one or both risers 152 and gas line tubing 160. In at least one implementation, risers 152 may be coupled to process gas supply 724.

In at least one implementation, process gases may be preconditioned, for example, by passage through preheater assemblies 725 and 727 (e.g., as described for FIGS. 6A-6D), as well as surface mount components on surface mount substrate 502 (e.g., surface mount components 104). In at least one implementation, process gas handling components may include flow control valves, mixers, and gas filters. In at least one implementation, process gas reservoir subassemblies 118 and 120 may be heated by heater cartridges 726 within reservoir housing blocks 126 and 128 so that process gases held within charge volume cannisters (e.g., charge volume cannisters 202a and 202b, FIG. 5B) may be maintained at elevated temperatures. In at least one implementation, heater cartridges 726 may be electrical heater cartridges coupled to temperature controller 728.

In at least one implementation, cold spots within surface mount components 104, for example, may lead to condensation or crystallization within interior passages of the surface mount components. In at least one implementation, surface mount components 104 may be heated by thermal contact with nonplanar sidewalls 144 and 154, respectively. In at least one implementation, risers 152 may also be maintained at elevated temperatures by thermal contact with sidewall grooves (e.g., grooves 150 within nonplanar sidewall 144 and grooves 158 within nonplanar sidewall 154) in reservoir housing blocks 126 and 128, respectively.

In at least one implementation, showerhead inlet adapter 721 may also comprise internal heating elements to prevent condensation of vapors within conduits 708, 710, and 712, prior to entering showerhead 704. In at least one implementation, during operation, process gases may issue from showerhead 704 into vacuum chamber 702. In at least one implementation, process gases issuing from showerhead 704 may be directed to wafer 730 supported on pedestal 732, comprising chuck 734 and column 736. In at least one implementation, showerhead 704 may distribute process gases in laminar flow for atomic layer deposition (ALD) or chemical vapor deposition (CVD) processes. In at least one implementation, ALD or CVD processes may form amorphous, monocrystalline, or polycrystalline films on the surface of wafer 730. In at least one implementation, wafer 730 may be heated by chuck 734 to elevated temperatures supporting formation of amorphous, monocrystalline, or polycrystalline films.

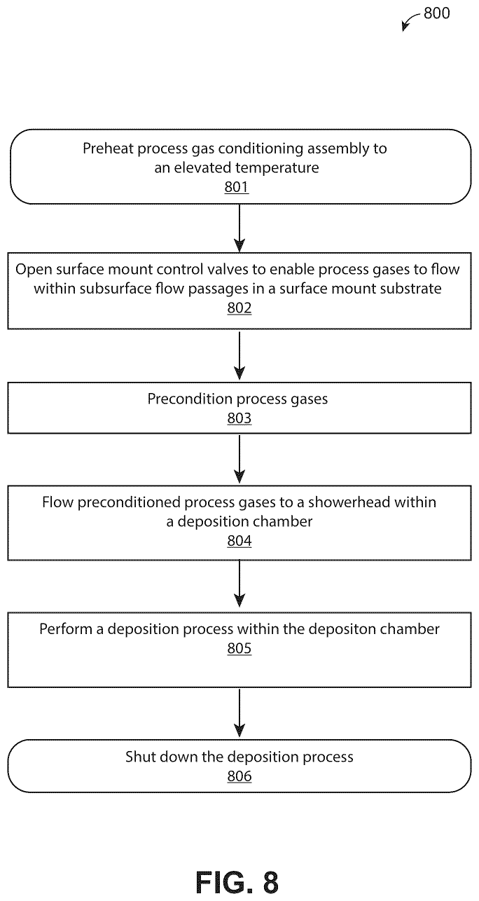

FIG. 8 illustrates a flow chart 800 for a method for operating process gas conditioning assembly 100 (also process gas conditioning assemblies 300 and 500), in accordance with at least one implementation. Various operations of flow chart 800 may be performed by hardware, software, or a combination of them. In at least one implementation, method flow chart 800 illustrates an exemplary operation of the disclosed process gas conditioning assembly, such as process gas conditioning assembly 100, to precondition process gases employed in semiconductor process operations. In at least one implementation, process gases may be preconditioned by process gas conditioning assembly 100, for example, prior to entry into a semiconductor process tool (e.g., semiconductor process tool 700, shown in FIG. 7).

In at least one implementation, at operation 801, process gas conditioning assembly 100 is preheated to a predetermined elevated temperature. In at least one implementation, preheating may comprise activation of heating integral heating cartridges by a temperature controller.

In at least one implementation, as temperatures of process gas conditioning assembly stabilize 100, process gases held within the change volume cannisters (e.g., charge volume cannisters 202 and 204, as shown in FIG. 2) may commence flowing within the subsurface flow passages (e.g., gas flow passage 108) of the surface mount substrate (e.g., surface mount substrate 102 or 502).

In at least one implementation, at operations 802 and 803, surface mount valves may open, for example by electronic command sent to an actuator on the valves, to initiate flow of process gases into gas line tubing coupled to the surface mount substrate. In at least one implementation, the gas line tubing may pass through a preheater stage (e.g., preheater assembly 600). In at least one implementation, the preheater stage may preheat process gases flowing within the gas line tubing to a temperature closely matching the temperature of the process gas conditioning assembly. In at least one implementation, flow of process gases may then proceed within the subsurface flow passages.

In at least one implementation, process gases may also flow through any surface mount component attached to the surface mount substrate, as they are fluidically coupled to the subsurface flow passages. In at least one implementation, surface mount components may control flow rate, divert flow to other paths, mix reactive process gases with inert or reactive carrier gases, filter particulates from process gases, etc. In at least one implementation, preconditioning process gases prior to entry into the semiconductor process tool may comprise passive heating, mixing, and filtering of process gases flowing within the subsurface flow passages in the surface mount substrate.

In at least one implementation, at operations 804 and 805, the process gas flow may enter a deposition process chamber (e.g., vacuum chamber 702 shown in FIG. 7) of a semiconductor process tool (e.g., semiconductor process tool 700). Within the deposition process chamber, a deposition process may be performed by issuing the preconditioned process gases through a showerhead (e.g., showerhead 704 shown in FIG. 7) into the deposition process chamber. In at least one implementation, as the chamber is held at a high vacuum, the preconditioned process gases may issue from orifices in the showerhead in a plurality of laminar flow jets. In at least one implementation, process gases may include reactive and inert carrier gases, mixing gases, and vapors from precursor substances that are liquid or solid at room temperature.

In at least one implementation, preconditioned process gases may impinge on a wafer below the showerhead (e.g., wafer 730 shown in FIG. 7). In at least one implementation, depending on the process conditions, surface reactions, and the nature of the precursor substances, crystalline thin films may be grown on the wafer as atomic or molecular layers. In at least one implementation, layers may be built up to form films of desired thicknesses. In at least one implementation, in some processes, the thin films are amorphous.

In at least one implementation, at operation 806, the process may be shut down by ceasing process gas flow. In at least one implementation, stopping flow of process gases may comprise closing control surface mount valves on the surface mount substrate. In at least one implementation, heating cartridges may remain activated to permit carrier gases to purge remaining condensable vapors. In at least one implementation, purge duration may be predetermined. In at least one implementation, once all condensable vapors are purged, heating cartridges may be powered down to allow the process gas conditioning assembly to cool.

The following examples are provided that illustrate the various embodiments. The examples can be combined with other examples. As such, various embodiments can be combined with other embodiments without changing the scope of the invention.

Example 1 is a gas conditioning assembly, comprising a surface mount substrate, wherein the surface mount substrate comprises a plurality of apertures, wherein a first gas flow passage extends within the surface mount substrate, and wherein a second gas flow passage is adjacent to the first gas flow passage; and a process gas reservoir subassembly, wherein the process gas reservoir subassembly is adjacent to the surface mount substrate and comprises a reservoir housing block and a reservoir yoke, wherein the reservoir yoke comprises at least one gas reservoir within the reservoir housing block, wherein the reservoir housing block comprises a nonplanar sidewall adjacent to the surface mount substrate, wherein the nonplanar sidewall comprises a plurality of recessed contours and a plurality of grooves extending along the nonplanar sidewall, wherein one or more recessed contours are in thermal contact with one or more surface mount components mounted on the surface mount substrate, and wherein one or more grooves are in thermal contact with one or more gas line tubing sections extending from the surface mount substrate.

Example 2 is the gas conditioning assembler of any of the examples, in particular example 1, wherein one or more first surface mount components are fluidically coupled to the first gas flow passage, and wherein one or more second surface mount components are fluidically coupled to the second gas flow passage.

Example 3 is the gas conditioning assembler of any of the examples, in particular example 1, wherein the one or more gas line tubing sections are in thermal contact with the one or more grooves.

Example 4 is the gas conditioning assembler of any of the examples, in particular example 1, wherein the at least one gas reservoir is fluidically coupled to the first gas flow passage.

Example 5 is the gas conditioning assembler of any of the examples, in particular example 1, wherein the reservoir housing block comprises a surface orthogonal to the nonplanar sidewall, and wherein at least one reservoir well is substantially orthogonal to the surface.

Example 6 is the gas conditioning assembler of any of the examples, in particular example 1, wherein the reservoir housing block comprises a surface, and wherein at least one reservoir well is substantially parallel to the surface.

Example 7 is the gas conditioning assembler of any of the examples, in particular example 6, wherein the one or more surface mount components comprise an inlet and an outlet, wherein the inlet is fluidically coupled to a first aperture on the surface of the surface mount substrate, and wherein the outlet is fluidically coupled to a second aperture on the surface of the surface mount substrate.

Example 8 is the gas conditioning assembler of any of the examples, in particular example 1, wherein the reservoir housing block further comprises a first plurality of heater cartridges.

Example 9 is the gas conditioning assembler of any of the examples, in particular example 1, wherein the one or more recessed contours comprise a circular arc.

Example 10 is the gas conditioning assembler of any of the examples, in particular example 1, wherein the one or more recessed contours are in mechanical contact with the one or more surface mount components.

Example 11 is the gas conditioning assembler of any of the examples, in particular example 1, wherein a gap is between the one or more recessed contours and the one or more surface mount components.

Example 12 is the gas conditioning assembler of any of the examples, in particular example 1, further comprising a heated panel, wherein the heated panel comprises a first face and a second face, wherein the first face is adjacent to a first frontal sidewall of the reservoir housing block, and wherein the first face is adjacent to a second frontal sidewall of the surface mount substrate.

Example 13 is the gas conditioning assembler of any of the examples, in particular example 12, wherein the one or more grooves extend along the first face, and wherein the one or more grooves are in thermal contact with the one or more gas line tubing sections.

Example 14 is the gas conditioning assembler of any of the examples, in particular example 12, wherein the heated panel comprises one or more heater cartridges, within heater cartridge wells, extending between the first face and the second face.

Example 15 is the gas conditioning assembler of any of the examples, in particular example 1, wherein the nonplanar sidewall is a first nonplanar sidewall, wherein the first nonplanar sidewall comprises one or more first recessed contours, wherein the one or more grooves comprise a first groove, wherein a heated panel is adjacent to the surface mount substrate, wherein the heated panel comprises a second nonplanar sidewall adjacent to the surface mount substrate, and wherein the second nonplanar sidewall comprises a plurality of second recessed contours and a plurality of second grooves extending along the second nonplanar sidewall.

Example 16 is the gas conditioning assembler of any of the examples, in particular example 1, wherein the reservoir yoke comprises a manifold which is fluidically coupled to the at least one gas reservoir.

Example 17 is a semiconductor process tool, comprising a vacuum chamber; a showerhead within the vacuum chamber; and a gas conditioning assembly mechanically coupled to the vacuum chamber, comprising a surface mount substrate, wherein the surface mount substrate comprises a plurality of apertures, wherein a first gas flow passage extends within the surface mount substrate, and wherein a second gas flow passage is adjacent to the first gas flow passage; and a process gas reservoir subassembly, wherein the process gas reservoir subassembly is adjacent to the surface mount substrate and comprises a reservoir housing block and a reservoir yoke, wherein the reservoir yoke comprises at least one gas reservoir within the reservoir housing block, wherein the reservoir housing block comprises a nonplanar sidewall adjacent to the surface mount substrate, wherein the nonplanar sidewall comprises a plurality of recessed contours and a plurality of grooves extending along the nonplanar sidewall, wherein one or more recessed contours are in thermal contact with one or more surface mount components mounted on the surface mount substrate, and one or more grooves are in thermal contact with one or more gas line tubing sections extending from the surface mount substrate, and wherein the gas conditioning assembly is fluidically coupled to the showerhead.

Example 18 is the semiconductor process tool of any of the examples, in particular example 17, wherein a first conduit and a second conduit extend between the surface mount substrate and the showerhead, wherein the first conduit is fluidically coupled to the first gas flow passage and to the showerhead, and wherein the second conduit is fluidically coupled to the second gas flow passage and to the showerhead.

Example 19 is the semiconductor process tool of any of the examples, in particular example 18, wherein the first conduit and the second conduit extend within a showerhead inlet adapter, wherein the showerhead inlet adapter comprises a cavity, wherein the first conduit and the second conduit extend within the cavity, wherein at least the first conduit terminates at a first annular aperture, and wherein the first annular aperture opens into the showerhead.

Example 20 is the semiconductor process tool of any of the examples, in particular example 19, wherein a third gas flow passage extends within the surface mount substrate, wherein the third gas flow passage is adjacent to the first gas flow passage and to the second gas flow passage, and wherein a third conduit extends with the showerhead inlet adapter, and wherein the third conduit is fluidically coupled to the third gas flow passage and terminates at a second annular aperture, and wherein the second annular aperture opens into the showerhead.

Example 21 is the semiconductor process tool of any of the examples, in particular example 17, wherein the gas conditioning assembly further comprises at least one preheater assembly coupled to the one or more gas line tubing sections.

Example 22 is the semiconductor process tool of any of the examples, in particular example 21, wherein the at least one preheater assembly comprises two or more plates in a stack assembly, and wherein the one or more gas line tubing sections extend between adjacent plates, and wherein the two or more plates comprise heater cartridges.

Example 23 is the semiconductor process tool of any of the examples, in particular example 22, wherein the two or more plates comprise at least two middle plates between a first end cap plate and a second end cap plate, wherein the at least two middle plates are substantially identical.

Example 24 is the semiconductor process tool of any of the examples, in particular example 22, wherein the one or more gas line tubing sections are arranged in a serpentine configuration, and wherein the one or more gas line tubing sections extend within one or more grooves on the two or more plates.

Example 25 is the semiconductor process tool of any of the examples, in particular example 21, wherein the at least one preheater assembly has a rhomboidal cross section in at least one plane.

Example 26 is a method for conditioning a process gas, comprising providing a semiconductor process tool comprising a process gas conditioning assembly, wherein the process gas conditioning assembly comprises a surface mount substrate, wherein the surface mount substrate comprises a plurality of apertures, wherein a first gas flow passage extends within the surface mount substrate, and wherein a second gas flow passage is adjacent to the first gas flow passage; and a process gas reservoir subassembly, wherein the process gas reservoir subassembly is adjacent to the surface mount substrate and comprises a reservoir housing block and a reservoir yoke, wherein the reservoir yoke comprises at least one gas reservoir within the reservoir housing block, wherein the reservoir housing block comprises a nonplanar sidewall adjacent to the surface mount substrate, wherein the nonplanar sidewall comprises a plurality of recessed contours and a plurality of grooves extending along the nonplanar sidewall, wherein one or more recessed contours are in thermal contact with one or more surface mount components mounted on the surface mount substrate, and one or more grooves are in thermal contact with one or more gas line tubing sections extending from the surface mount substrate; preheating the surface mount substrate and the reservoir housing block of the process gas reservoir subassembly to an elevated temperature; preconditioning at least one process gas flowing through at least the first gas flow passage within the surface mount substrate, wherein the at least one process gas is preheated; and flowing the at least one process gas through a showerhead into a vacuum chamber of the semiconductor process tool.

Example 27 is the method of any of the examples, in particular example 26, wherein preconditioning the at least one process gas comprises flowing the at least one process gas though the one or more gas line tubing sections, and wherein the one or more gas line tubing sections are in thermal contact with the one or more grooves extending within the nonplanar sidewall of the reservoir housing block.

Example 28 is the method of any of the examples, in particular example 26,wherein flowing the at least one process gas through the showerhead into the vacuum chamber comprises flowing the at least one process gas through at least one conduit, and wherein the at least one conduit is fluidically coupled to at least the first gas flow passage and the showerhead.

Example 29 is the method of any of the examples, in particular example 28, wherein flowing the at least one process gas through the at least one conduit comprises flowing the at least one process gas into the showerhead through an annular aperture within a showerhead inlet adapter, wherein the at least one conduit extends through the showerhead inlet adapter, and wherein the annular aperture is fluidically coupled to the showerhead.

Besides what is described herein, various modifications may be made to the disclosed embodiments and implementations thereof without departing from their scope. Therefore, illustrations of embodiments herein should be construed as examples only, and not restrictive to the scope of the present disclosure. The scope of the invention should be measured solely by reference to the claims that follow.

We claim:

1. A gas conditioning assembly, comprising:
a surface mount substrate, wherein the surface mount substrate comprises a plurality of apertures, wherein a first gas flow passage extends within the surface mount substrate, and wherein a second gas flow passage is adjacent to the first gas flow passage; and
a process gas reservoir subassembly, wherein the process gas reservoir subassembly is adjacent to the surface mount substrate and comprises a reservoir housing block and a reservoir yoke, wherein the reservoir yoke comprises at least one gas reservoir within the reservoir housing block, wherein the reservoir housing block comprises a nonplanar sidewall adjacent to the surface mount substrate, wherein the nonplanar sidewall comprises a plurality of recessed contours and a plurality of grooves extending along the nonplanar sidewall,
wherein one or more recessed contours are in thermal contact with one or more surface mount components mounted on the surface mount substrate, and wherein one or more grooves are in thermal contact with one or more gas line tubing sections extending from the surface mount substrate.

2. The gas conditioning assembly of claim 1, wherein one or more first surface mount components are fluidically coupled to the first gas flow passage, and wherein one or more second surface mount components are fluidically coupled to the second gas flow passage.

3. The gas conditioning assembly of claim 1, wherein the one or more gas line tubing sections are in thermal contact with the one or more grooves.

4. The gas conditioning assembly of claim 1, wherein the at least one gas reservoir is fluidically coupled to the first gas flow passage.

5. The gas conditioning assembly of claim 1, wherein the reservoir housing block comprises a surface orthogonal to the nonplanar sidewall, and wherein at least one reservoir well is substantially orthogonal to the surface.

6. The gas conditioning assembly of claim 1, wherein the reservoir housing block comprises a surface, and wherein at least one reservoir well is substantially parallel to the surface.

7. The gas conditioning assembly of claim 6, wherein the one or more surface mount components comprise an inlet and an outlet, wherein the inlet is fluidically coupled to a first aperture on the surface of the surface mount substrate, and wherein the outlet is fluidically coupled to a second aperture on the surface of the surface mount substrate.

8. The gas conditioning assembly of claim 1, wherein the reservoir housing block further comprises a first plurality of heater cartridges.

9. The gas conditioning assembly of claim 1, wherein the one or more recessed contours comprise a circular arc.

10. The gas conditioning assembly of claim 1, wherein the one or more recessed contours are in mechanical contact with the one or more surface mount components.

11. The gas conditioning assembly of claim 1, wherein a gap is between the one or more recessed contours and the one or more surface mount components.

12. The gas conditioning assembly of claim 1, further comprising a heated panel, wherein the heated panel comprises a first face and a second face, wherein the first face is adjacent to a first frontal sidewall of the reservoir housing block, and wherein the first face is adjacent to a second frontal sidewall of the surface mount substrate.

13. The gas conditioning assembly of claim 12, wherein the one or more grooves extend along the first face, and wherein the one or more grooves are in thermal contact with the one or more gas line tubing sections.

14. The gas conditioning assembly of claim 12, wherein the heated panel comprises one or more heater cartridges, within heater cartridge wells, extending between the first face and the second face.

15. The gas conditioning assembly of claim 1, wherein the nonplanar sidewall is a first nonplanar sidewall, wherein the first nonplanar sidewall comprises one or more first recessed contours, wherein the one or more grooves comprise a first groove, wherein a heated panel is adjacent to the surface mount substrate, wherein the heated panel comprises a second nonplanar sidewall adjacent to the surface mount substrate, and wherein the second nonplanar sidewall comprises a plurality of second recessed contours and a plurality of second grooves extending along the second nonplanar sidewall.

16. The gas conditioning assembly of claim 1, wherein the reservoir yoke comprises a manifold which is fluidically coupled to the at least one gas reservoir.

17. A semiconductor process tool, comprising:
a vacuum chamber;
a showerhead within the vacuum chamber; and
a gas conditioning assembly mechanically coupled to the vacuum chamber, comprising:
a surface mount substrate, wherein the surface mount substrate comprises a plurality of apertures, wherein a first gas flow passage extends within the surface mount substrate, and wherein a second gas flow passage is adjacent to the first gas flow passage; and
a process gas reservoir subassembly, wherein the process gas reservoir subassembly is adjacent to the surface mount substrate and comprises a reservoir housing block and a reservoir yoke, wherein the reservoir yoke comprises at least one gas reservoir within the reservoir housing block, wherein the reservoir housing block comprises a nonplanar sidewall adjacent to the surface mount substrate, wherein the nonplanar sidewall comprises a plurality of recessed contours and a plurality of grooves extending along the nonplanar sidewall,
wherein one or more recessed contours are in thermal contact with one or more surface mount components mounted on the surface mount substrate, and one or more grooves are in thermal contact with one or more gas line tubing sections extending from the surface mount substrate, and
wherein the gas conditioning assembly is fluidically coupled to the showerhead.

18. The semiconductor process tool of claim 17, wherein a first conduit and a second conduit extend between the surface mount substrate and the showerhead, wherein the first conduit is fluidically coupled to the first gas flow passage and to the showerhead, and wherein the second conduit is fluidically coupled to the second gas flow passage and to the showerhead.

19. The semiconductor process tool of claim 18, wherein the first conduit and the second conduit extend within a showerhead inlet adapter, wherein the showerhead inlet adapter comprises a cavity, wherein the first conduit and the second conduit extend within the cavity, wherein at least the first conduit terminates at a first annular aperture, and wherein the first annular aperture opens into the showerhead.

20. The semiconductor process tool of claim 19, wherein a third gas flow passage extends within the surface mount substrate, wherein the third gas flow passage is adjacent to the first gas flow passage and to the second gas flow passage, and wherein a third conduit extends with the showerhead inlet adapter, and wherein the third conduit is fluidically coupled to the third gas flow passage and terminates at a second annular aperture, and wherein the second annular aperture opens into the showerhead.

21. The semiconductor process tool of claim 17, wherein the gas conditioning assembly further comprises at least one preheater assembly coupled to the one or more gas line tubing sections.

22. The semiconductor process tool of claim 21, wherein the at least one preheater assembly comprises two or more plates in a stack assembly, and wherein the one or more gas line tubing sections extend between adjacent plates, and wherein the two or more plates comprise heater cartridges.

23. The semiconductor process tool of claim 22, wherein the two or more plates comprise at least two middle plates between a first end cap plate and a second end cap plate, wherein the at least two middle plates are substantially identical.

24. The semiconductor process tool of claim 22, wherein the one or more gas line tubing sections are arranged in a serpentine configuration, and wherein the one or more gas line tubing sections extend within one or more grooves on the two or more plates.

25. The semiconductor process tool of claim 21, wherein the at least one preheater assembly has a rhomboidal cross section in at least one plane.

26. A method for conditioning a process gas, comprising:
providing a semiconductor process tool comprising a process gas conditioning assembly, wherein the process gas conditioning assembly comprises:
a surface mount substrate, wherein the surface mount substrate comprises a plurality of apertures, wherein a first gas flow passage extends within the surface mount substrate, and wherein a second gas flow passage is adjacent to the first gas flow passage; and
a process gas reservoir subassembly, wherein the process gas reservoir subassembly is adjacent to the surface mount substrate and comprises a reservoir housing block and a reservoir yoke, wherein the reservoir yoke comprises at least one gas reservoir within the reservoir housing block, wherein the reservoir housing block comprises a nonplanar sidewall adjacent to the surface mount substrate, wherein the nonplanar sidewall comprises a plurality of recessed contours and a plurality of grooves extending along the nonplanar sidewall,
wherein one or more recessed contours are in thermal contact with one or more surface mount components mounted on the surface mount substrate, and one or more grooves are in thermal contact with one or more gas line tubing sections extending from the surface mount substrate;
preheating the surface mount substrate and the reservoir housing block of the process gas reservoir subassembly to an elevated temperature;
preconditioning at least one process gas flowing through at least the first gas flow passage within the surface mount substrate, wherein the at least one process gas is preheated; and
flowing the at least one process gas through a showerhead into a vacuum chamber of the semiconductor process tool.

27. The method of claim 26, wherein preconditioning the at least one process gas comprises flowing the at least one process gas though the one or more gas line tubing sections, and wherein the one or more gas line tubing sections are in thermal contact with the one or more grooves extending within the nonplanar sidewall of the reservoir housing block.

28. The method of claim 26, wherein flowing the at least one process gas through the showerhead into the vacuum chamber comprises flowing the at least one process gas through at least one conduit, and wherein the at least one conduit is fluidically coupled to at least the first gas flow passage and the showerhead.

29. The method of claim 28, wherein flowing the at least one process gas through the at least one conduit comprises flowing the at least one process gas into the showerhead through an annular aperture within a showerhead inlet adapter, wherein the at least one conduit extends through the showerhead inlet adapter, and wherein the annular aperture is fluidically coupled to the showerhead.
